(19) United States
(12) Patent Application Publication
(10) Pub. No.: US 2023/0110324 A1
(43) Pub. Date: Apr. 13, 2023

(54) OPTICAL DEVICES WITH LATERAL CURRENT INJECTION

(71) Applicant: GOOGLE LLC, Mountain View, CA (US)

(72) Inventors: Aurelien Jean Francois David, San Francisco, CA (US); Melvin Barker Mclaurin, Oakland, CA (US)

(21) Appl. No.: 18/045,683

(22) Filed: Oct. 11, 2022

Related U.S. Application Data
(60) Provisional application No. 63/254,840, filed on Oct. 12, 2021.
(60) Provisional application No. 63/347,066, filed on May 31, 2022.

(51) Int. Cl. H01L 33/06; H01L 33/00; H01L 33/14; H01L 33/24; H01L 33/32; H01L 33/46

(52) U.S. Cl. CPC H01L 33/06; H01L 33/007; H01L 33/145; H01L 33/24; H01L 33/32; H01L 33/46

(57) ABSTRACT

In a general aspect, a micro-LED includes a semiconductor mesa having a lateral dimension less than 5 um along a horizontal direction of the micro-LED, and a contact formed on a non-horizontal face of the semiconductor mesa. The semiconductor mesa includes a plurality of quantum wells (QWs), and a p-type semiconductor layer formed between the contact and the plurality of QWs. The contact, the p-type semiconductor layer and the plurality of QWs are configured such that, when the micro-LED is driven at an effective current density less than 50 A/cm2, holes are injected from the contact to the plurality of QWs through the p-type semiconductor layer. The injected holes diffuse laterally in the plurality of QWs over a distance greater than 1 micrometer (μm).

### CROSS-REFERENCE TO RELATED APPLICATIONS

This application claims the priority benefit of U.S. Provisional Application No. 63/254,840, entitled “SMALL DEVICES WITH LATERAL CURRENT INJECTION”, filed Oct. 12, 2021, and of U.S. Provisional Application No. 63/347,066, entitled “SMALL DEVICES WITH LATERAL CURRENT INJECTION”, filed May 31, 2022, both of which are hereby incorporated by reference in their entireties.

### TECHNICAL FIELD

This description relates to optical devices. More specifically, this disclosure relates to design, development, manufacturing and operation of light-emitting diodes (LEDs), such as micro-LEDs.

### BACKGROUND

Light-emitting diodes (LEDs) are used in a number of applications, such as in various consumer electronic devices. For instance LEDs are widely used in display devices, such as, for example, in smartphones, computers, televisions, etc. As resolution of such displays increase (e.g., number of display pixels per inch), LEDs used to implement a display have been reduced in size to achieve such increases in display resolution. However, achieving desired performance (e.g., efficiency, brightness, etc.) as dimensions of LEDs decrease has become a challenge. One approach that has been implemented is to increase a number of light emitting layers, or regions, i.e., stacked quantum wells (QWs), of such LEDs. However, such approaches are limited in their benefit, as only a portion (e.g., one or two) of the QWs of a stack may emit light (e.g., light that can be perceived by a viewer).

### SUMMARY

In one general aspect, the techniques described herein relate to a method for electrical operation of a micro-LED. The method includes driving the micro-LED with an electrical power via at a p-type contact disposed on at least one of: a horizontal face of the micro-LED; or a non-horizontal face of the micro-LED, where the p-type contact contacts a p-type layer. The method further includes injecting, by driving the micro-LED with the electrical power, holes from the p-type contact into the p-type layer, and laterally injecting, along the non-horizontal face of the micro-LED, the holes from the p-type layer to a plurality of quantum wells (QWs). The plurality of QWs have respective horizontal regions arranged along a horizontal direction of the micro-LED, the holes being laterally injected to the plurality of QWs via the p-type semiconductor layer.

Implementations can include one or more of the following features in various combinations. In some aspects, the micro-LED can have a lateral dimension along the horizontal direction between 0.5 micrometers (μm) and 5 μm. The injected holes can diffuse laterally in the plurality of QWs over a distance greater than 0.5 μm.

In some aspects, the non-horizontal face can be arranged along a semi-polar plane of the micro-LED.

In some aspects, at least one QW of the plurality of QWs can have a recombination lifetime greater than 5 nanoseconds (ns) corresponding with the driving of the micro-LED with the electrical power.

In some aspects, driving the micro-LED with the electrical power can include driving the micro-LED with a current density between 1 amp/centimeter-squared (A/cm2) and 100 A/cm2.

In another general aspect, the techniques described herein relate to a micro-LED that includes a semiconductor mesa having a lateral dimension less than Sum along a horizontal direction of the micro-LED. The micro-LED also includes a contact formed on at least one of: a horizontal face of the semiconductor mesa, or a non-horizontal face of the semiconductor mesa. The semiconductor mesa includes a plurality of quantum wells (QWs), and a p-type semiconductor layer formed between the contact and the plurality of QWs. The contact, the p-type semiconductor layer and the plurality of QWs are configured such that, when the micro-LED is driven at an effective current density less than 50 A/cm2, holes are injected from the contact to p-type layer; and laterally injected from the p-type layer to the plurality of QWs, where the injected holes diffuse laterally in the plurality of QWs over a distance greater than 1 micrometer (μm).

Implementations can include one or more of the following features in various combinations. In some aspects, the non-horizontal face can be a slanted sidewall of the semiconductor mesa. The slanted sidewall can be arranged at an angle between 10 degrees and 80 degrees with respect to a line along the horizontal direction.

In some aspects, the non-horizontal face can be arranged along a semi-polar plane of the semiconductor mesa.

In some aspects, the plurality of QWs can include at least three QWs. Respective percentages of the injected holes that are diffused in the at least three QWs are less than 50 percent and greater than 25 percent.

In another general aspect, the techniques described herein relate to a micro-LED mesa including a semiconductor mesa having a lateral dimension along a horizontal direction of the micro-LED mesa of less than or equal to 5 micrometers (μm). The semiconductor mesa includes at least one slanted sidewall, a planar top surface, and a multiple quantum well (MQW) portion having a planar region arranged along the planar top surface and a slanted region arranged along the at least one slanted sidewall. First p-type material is disposed on the planar region of the MQW portion, and second p-type material is disposed on the slanted region of the MQW portion. A p-type contact is disposed on the second p-type material.

Implementations can include one or more of the following features in various combinations. In some aspects, the micro-LED mesa can further include an insulating layer disposed on at least a portion of the first p-type material, and a reflective layer disposed on the insulating layer.

In some aspects, during electrical operation of the micro-LED mesa, hole injection can occur at a first carrier density through the first p-type material, and hole injection can occur at a second carrier density through the second p-type material. The second carrier density can be negligible relative to the first carrier density.

In some aspects, quantum wells (QWs) of the MQW portion have respective diffusion coefficients of greater than or equal to 1 centimeter-squared per second (cm2/s) at a current density of less than 20 amps per centimeter-squared (A/cm2).

In some aspects, in response to injection of holes from the p-type contact, light can be emitted from the MQW portion at a lateral distance along the horizontal direction of greater than or equal to 1 micrometer (μm) from the p-type contact.

In some aspects, the micro-LED mesa can include a plurality of GaN-based materials.

In some aspects, the planar top surface can be arranged along a c-plane of at least one of the plurality of GaN based materials, and the at least one slanted sidewall can be arranged along a semi-polar plane of at least one of the plurality of GaN based materials.

In another general aspect, the techniques described herein relate to a micro-LED mesa include a semiconductor mesa having a horizontal top surface arranged along a horizontal direction of the micro-LED mesa, at least three non-vertical sidewalls, and a plurality of epitaxial layers. The plurality of epitaxial layers include a first portion arranged along the horizontal direction. The first portion of the plurality of epitaxial layers define a first plurality of quantum wells (QWs) of a first thickness and a first bandgap. The plurality of epitaxial layers also include a second portion arranged along the at least three non-vertical sidewalls. The second portion of the plurality of epitaxial layers define a second plurality of QWs of a second thickness and a second bandgap. The micro-LED further includes an electrical contact disposed on at least one non-vertical sidewall of the at least three non-vertical sidewalls.

Implementations can include one or more of the following features in various combinations. In some aspects, the micro-LED mesa can be configured such that holes, injected during electrical operation of the micro-LED mesa, travel from the electrical contact to the second plurality of QWs and, then to the first plurality of QWs.

In some aspects, the micro-LED mesa can be configured such that, during electrical operation of the micro-LED mesa, light is emitted from at least two QWs of the first plurality of QWs.

In some aspects, the first portion of the plurality of epitaxial layers can be included in a central portion of the micro-LED mesa. The central portion of the micro-LED mesa can have a lateral width along the horizontal direction of greater than or equal to 500 nanometers (nm).

In some aspects, the micro-LED mesa can have a width of less than or equal to 20 micrometers (μm), and a height of greater than or equal to 100 nanometers (nm). The height can be less than or equal to 10 μm.

In some aspects, the second portion of the plurality of epitaxial layers can be located in a perimeter portion of the micro-LED mesa.

In some aspects, the horizontal direction can be arranged along a c-plane of a crystalline structure of the micro-LED mesa. The at least three non-vertical sidewalls can be arranged along respective semipolar planes of the crystalline structure.

In some aspects, the at least three non-vertical sidewalls can have respective angles from a vertical direction of the micro-LED mesa that are between 10 degrees and 80 degrees.

In some aspects, the first plurality of QWs and the second plurality of QWs can be connected in a one-to-one relationship.

In some aspects, the second bandgap can be greater than the first bandgap.

In some aspects, the second thickness can be less than the first thickness.

In some aspects, the electrical contact can be a first electrical contact. The micro-LED mesa can include a second electrical contact disposed on the horizontal top surface.

In another general aspect, the techniques described herein relate to a method for electrical operation of a micro-LED mesa. The micro-LED mesa includes at least one non-vertical sidewall including a p-type material with a first bandgap and a first thickness. The micro-LED mesa also includes an epitaxial layer with a second bandgap and a second thickness. The p-type material is disposed on the epitaxial layer. The micro-LED mesa further includes a plurality of quantum wells (QWs) with a planar orientation along a horizontal direction of the micro-LED mesa, a third bandgap, and a third thickness. The epitaxial layer is disposed between the p-type material and the plurality of QWs. The micro-LED mesa also includes an electrical contact disposed on the p-type material. The first bandgap is greater than the second bandgap, the second bandgap is greater than the third bandgap, and the second thickness is less than the third thickness. The method includes injecting a plurality of holes from the electrical contact to the p-type material, injecting the plurality of holes from the p-type material to the epitaxial layer, and injecting the plurality of holes from the epitaxial layer to at least two QWs of the plurality of QWs.

Implementations can include one or more of the following features in various combinations. In some aspects, the p-type material can include p-type gallium nitride (GaN).

In some aspects, the epitaxial layer can be a non-planar and non-vertical QW arranged along a semi-polar plane of the micro-LED mesa. The epitaxial layer can include at least 1 percent indium. The plurality of QWs with the planar orientation can include at least 15 percent indium.

In some aspects, injecting the plurality of the holes into the plurality of QWs can include injecting no more than 30 percent of the plurality of holes into a single QW of the plurality of QWs.

In some aspects, the injected plurality of holes diffuse laterally along the horizontal direction in the plurality of QWs for a distance of greater than or equal to 500 nanometers (nm).

In some aspects, injecting the plurality of holes from the p-type material to the epitaxial layer can include injecting the plurality of holes through an electron blocking layer (EBL).

### BRIEF DESCRIPTION OF THE DRAWINGS

FIG. 1 is a diagram illustrating an example micro-LED (micro-LED mesa).

FIG. 2 is a diagram illustrating another example micro-LED.

FIG. 3 is a diagram illustrating another example micro-LED.

FIG. 4 is a diagram illustrating another example micro-LED.

FIG. 5 is a diagram illustrating another example micro-LED.

FIG. 6 is a diagram illustrating another example micro-LED.

FIG. 7 is a diagram illustrating another example micro-LED.

FIG. 8 is a diagram illustrating another example micro-LED.

FIG. 9 is a diagram illustrating another example micro-LED.

FIG. 10 is a diagram schematically illustrating an example epitaxial layer stack that can be included in a micro-LED, such as the micro-LEDs of FIGS. 1-9.

FIG. 11 is a diagram illustrating the example epitaxial layer stack and associated slanted sidewall.

FIG. 12 is a graph illustrating a model of a QW that can be included in a micro-LED.

FIGS. 13A to 13D are graphs illustrating the effect of quantum well thickness on operation of an LED.

FIGS. 14A to 14D are graphs illustrating the effect of indium content in a QW on operation of an LED.

FIGS. 15A and 15B are diagrams schematically illustrating, respectively, carrier density and light emission in an LED, such as the example implementations of the micro-LEDs of FIG. 1-9.

FIG. 16 is a graph illustrating a relationship between current density and internal quantum efficiency of example micro-LEDs.

FIG. 17 is a is a graph illustrating a relationship between current density and emitted light wavelength of example micro-LEDs.

FIGS. 18A to 18D are diagrams illustrating a process for producing a micro-LED, such as, at least, the micro-LEDs of FIGS. 2 and 3.

FIGS. 19A to 19D are diagrams illustrating a process for producing a micro-LED, such as, at least, the micro-LEDs of FIG. 6.

FIGS. 20A to 20D are diagrams illustrating a process for producing a micro-LED, such as, at least, the micro-LEDs of FIG. 7.

FIGS. 21A to 21D are diagrams illustrating a process for producing a micro-LED, such as, at least, the micro-LEDs of FIG. 8.

FIG. 22 is a diagram illustrating an LED in which lateral carrier diffusion occurs in doped layers other than QW layers.

FIG. 23 is a diagram illustrating another LED in which lateral carrier diffusion occurs in doped layers other than QW layers.

FIG. 24 is a diagram illustrating another LED in which lateral carrier diffusion occurs in doped layers other than QW layers.

FIGS. 25A to 25H are diagrams illustrating a process for producing the LED of FIG. 24.

FIG. 26 is a block diagram schematically illustrating a layout of a plurality of LEDs, such as the LEDs of FIGS. 22-24.

FIGS. 27A and 27B are circuit schematic diagrams illustrating circuit equivalents of example LEDs, such as the LEDs of FIGS. 23 and 24, respectively.

FIGS. 28A to 28C are diagram illustrating examples of LEDs (micro-LEDs) with slanted sidewalls with respective, different perimeter shapes.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in the same view, or in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated in a given view.

### DETAILED DESCRIPTION

Conventional light-emitting diodes (LEDs), such as LEDs used in display devices, operate via vertical electrical carrier injection. That is, injected electrical carriers, particularly holes, travel in a direction that is parallel to a growth direction for epitaxial layers included in the LEDs, e.g., to reach light emitting regions, such as quantum wells (QWs). Improving the performance of LEDs that operate with vertical carrier injection can be challenging.

The present disclosure relates to optoelectronic devices, which are referred to herein as micro-LEDs (or LEDs), in which electrical carrier injection occurs, at least in part, in a lateral direction, or a horizontal direction, e.g., in a direction that is perpendicular to an epitaxial layer growth direction. While the disclosed embodiments are generally described with respect to small devices, e.g., with lateral dimensions on the order of 10 micrometers (μm), or less, in some implementations, the approaches described herein can be used to implement larger devices, e.g., LEDs with lateral dimensions of 100 μm or more, 500 μm or more, or 1 millimeter (mm) or more. As used in the present disclosure, the terms horizontal, lateral and vertical are referenced relative to corresponding structure of the example LEDs (e.g., micro-LEDs) described herein. That is, horizontal and/or lateral refer to a direction that is perpendicular to a growth direction of epitaxial layers used to implement an LED, while vertical refers to a direction that is parallel to, or in a same direction as, the epitaxial growth direction. Also in the present disclosure, the terms LED and micro-LED (μLED) may be used interchangeably. Further, LEDs and micro-LEDs may also be referred to as devices, optical devices, etc. The terms carrier and electrical carrier can be used interchangeably, and can refer to holes and/or electrons.

In some implementations, such as the example devices described herein, lateral carrier injection can improve the performance of such micro-LEDs as compared to prior approaches, as it can allow for light emission from more QWs than prior device implementations, can improve light emission distribution, etc. In the example implementations, such lateral carrier injection can occur in doped layers (e.g., doped semiconductor layers), in light-emitting layers (e.g., QWs), or in a combination thereof. For instance, the present disclosure is directed to LEDs in which lateral carrier diffusion occurs in an active, or QW region, and/or to LEDs in which lateral carrier diffusion occurs in doped layers (e.g., n-type semiconductor layers and/or p-type semiconductor layers).

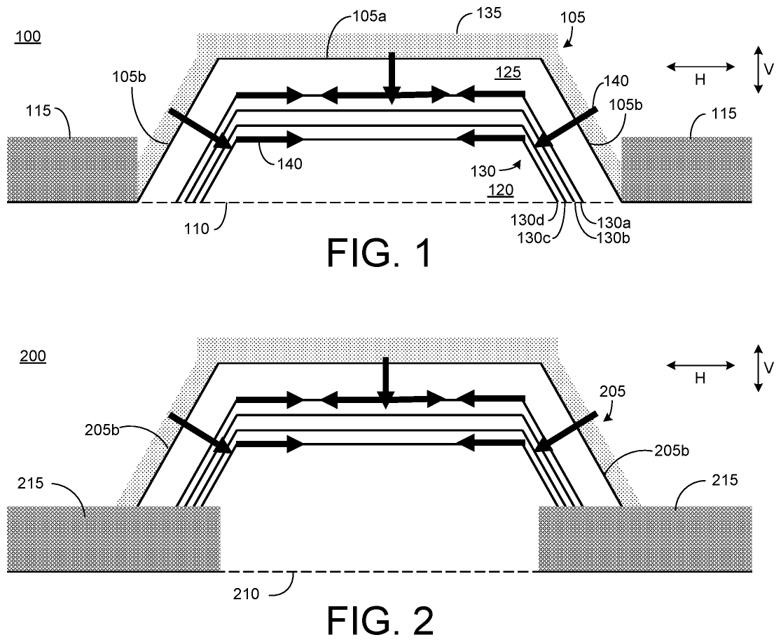

In some examples, such as the examples of FIGS. 1 to 9, lateral carrier injection and diffusion occurs, at least in part, in light-emitting QW layers. As described herein, such lateral carrier injection and diffusion can provide performance improvements for an associated device, e.g., a micro-LED or LED. For instance, using the approaches described herein, an LED can be configured such that the carriers can diffuse laterally across a sufficient distance to achieve improved carrier density distribution, improved light emission distribution, and/or improved quantum efficiency. In some implementations, the approaches described herein can allow for substantial carrier injection and diffusion in QWs that are located toward an n-side of a LED's QW stack, which can be difficult to achieve, or even not possible to achieve in implementations with three or more QWs included in a QW stack.

For instance, in some implementations, electrical carriers are laterally injected into a plurality of QWs of a QW stack from a non-vertical contact, e.g., a contact and/or p-type region included in, or disposed on a slanted (non-vertical and non-horizontal sidewall). Using the approaches described herein, an associated LED can be configured such that the injected carriers diffuse laterally in the QWs for a desired distance (e.g., diffusion length), e.g., 0.5 micrometers (μm) or more before recombining and emitting light.

In the example implementations described herein, performance improvements are achieved, at least in part, based on the determination that carrier diffusion lengths in a QW, instead of being a constant value, depend both on the epitaxial configuration (e.g. composition, thickness and micro-structure of a QW) and on carrier density in the QW during electrical operation of an associated LED. For instance, diffusion length in a QW can be expressed by Equation 1 as follows:

L=sqrt(D*tau(n)) (1),

where D is a diffusion coefficient, and tau(n) is a recombination lifetime (or carrier lifetime), which is a function of a carrier density n and, accordingly, depends on an injected current density J. Therefore, a desired value for a diffusion length L can be achieved by jointly configuring (adjusting, altering, modifying, etc.) the diffusion coefficient D and the current density n for a given LED to predetermined values. This approach can be applied for both holes and electrons, and the diffusion coefficient D can be an ambipolar diffusion coefficient.

In some implementations, an ambipolar diffusion coefficient D (e.g., for a QW of an LED), which can be an average of a hole diffusion coefficient Dₕ and an electron diffusion coefficient Dₑ, can be increased using a number of approaches. For instance, an increased value of D can be achieved by implementing a QW active region with sharp interfaces, e.g., with a transition region of less than 0.5 nanometers (nm), less than 0.3 nm, or less than 0.1 nm between the QW and associated barrier materials. Increased values of D can also be achieved by reducing atomic disorder in a QW, e.g., by producing InGaN QWs using growth conditions that reduce atomic disorder to be less that of a random alloy distribution. Using such approaches, diffusion coefficients D of at least 6 centimeters-squared per second (cm²/s), at least 8 cm²/s, or at least 10 cm2/s can be achieved.

The carrier lifetime, e.g., in a QW, is governed by several factors. In one model, a carrier recombination rate R(n) is given by Equation 2 as follows:

R(n)=An+Bn²+Cn³ (2),

where with A is a Shockley-Read-Hall (SRH) coefficient, B is a radiative coefficient, C is an Auger coefficient, and n the carrier density, as previously discussed. The differential lifetime is then given by Equation 3 as follows:

1/tau=A+2Bn+3Cn². (³)

Based on this model, a number of approaches, or techniques can be used to achieve a desired carry lifetime (tau) and a corresponding desired diffusion length L. For instance, an LED may be driven at a specific current density J to affect carrier lifetime and carrier diffusion length. In some implementations, a current density J used to drive (electrically operate an LED) can be less than 1 A/cm², less than 2 A/cm², less than 3 A/cm², less than 5 A/cm², less than 10 A/cm², less than 20 A/cm², less than 30 A/cm², less than 50 A/cm², or less than 100 A/cm2. In some implementations, a current density J can be selected to achieve a carrier density n in a corresponding QW that is less than 1E17/cm³, less than 2E17/cm³, less than 3E17/cm³, less than 5E17/cm³, less than 1E18/cm³, less than 2E18/cm³, less than 3E18/cm³, less than 5E18/cm³, or less than 1E19/cm³.

In some implementations, QWs of an LED can be configured (produced) to have a desired (e.g., increased) SRH lifetime, such as by implementing epitaxial layer growth process that reduce the SRH coefficient A. For instance, such reductions in the SRH coefficient A for a given QW can be achieved by reducing a defect density in the QW. For example, in gallium nitride (GaN) based LEDs, a defect density of the associated QWs can be reduced through the use of underlayers containing indium gallium nitride (InGaN), and/or by increasing a thickness of the QWs, such that an overlap in electron and hole wavefunctions decreases. In some examples, a density of SRH-causing defects of less than 1E17/cm³, less than 1E16/cm³, less than 1E15/cm³, or less than 1E14/cm³ can be achieved. In some examples, a QW of an LED can have a thickness of at least 2.5 nm, at least 3 nm, at least 3.5 nm, or at least 4 nm, which can be implemented in combination with an In percentage composition in the QW of at least 20%, at least 25%, at least 30%, or at least 35%. In such implementations, a corresponding SRH lifetime t_SRH of at least 10 nanoseconds (ns), at least 20 ns, at least 50 ns, at least 100 ns, at least 200 ns, at least 500 ns, at least 1000 ns, at least 2000 ns, at least 5000 ns, or at least 10000 ns can be achieved. For clarity, t_SRH and the SRH coefficient A are related by Equation 4 as follows:

t_SRH=1/A (4).

In some implementations, QWs of an LED can be configured (produced) to have a desired (e.g., reduced) radiative coefficient B and/or a desired (e.g., reduced) Auger coefficient C, such as in the model described above. For instance, in some implementations, the B and C coefficients can be reduced by increasing QW thickness, such that electron-hole overlap decreases, and/or by adding barriers of appropriate composition, e.g. aluminum gallium nitride (AlGaN) barriers, in order to increase a polarization field in the QW. In some implementations, B can be less than 1E-10 cm³/s, less than 1E-11 cm³/s, less than 1E-12 cm³/s, less than 1E-13 cm³/s, or less than 1E-14 cm³/s). In some implementations, C can be less than 1E-30 cm⁶/s, less than 1E-31 cm⁶/s, less than 1E-32 cm⁶/s, less than 1E-33 cm⁶/s, or less than 1E-34 cm⁶/s).

It is noted that the current density n is a volume, three-dimensional (n3D) carrier density. Surface current density is a per area, two-dimensional (n2D) current density. Surface current density and volume carrier density are related by Equation 5 as follows:

n2D=n3D/t (5),

where t is a thickness of the active QW layer. In some example implementations, t may be 2 nm, 3 nm, or 4 nm, and t may be a nominal (effective) value rather than an exact (physical) value.

It is noted that for the example micro-LEDs (LEDs) described herein, definitions of current density may be ambiguous, dependent on the area, or the portion of an LED being considered or evaluated. Accordingly, for purposes of clarity, current density can be referred to herein as effective current density, where effective current density is defined as current (e.g., total current) divided by a corresponding area of a planar portion an LED's active (QW) region, where that area can be similar to an area of an upper surface of a mesa used to implement a corresponding micro-LED.

In some implementation, a diffusion coefficient for holes in an active region (in QWs) of an LED can be at least 2 cm²/s, e.g., with the LED being operated at an effective current density J of less than 50 A/cm², resulting in a recombination lifetime of more than 30 ns. In this example, the corresponding hole diffusion length would, therefore, be at least 2.5 μm. In one example implementation, the LED is a micro-LED (μLED) with a mesa having a lateral (horizontal) dimension of less than 5 um, and contacts (e.g., p-type contacts) formed on (disposed on) the sidewalls of the mesa. In this example, lateral diffusion over the diffusion length of 2.5 μm can lead to a substantial hole population even near the center of the mesa of the μLED device (e.g., a μLED mesa).

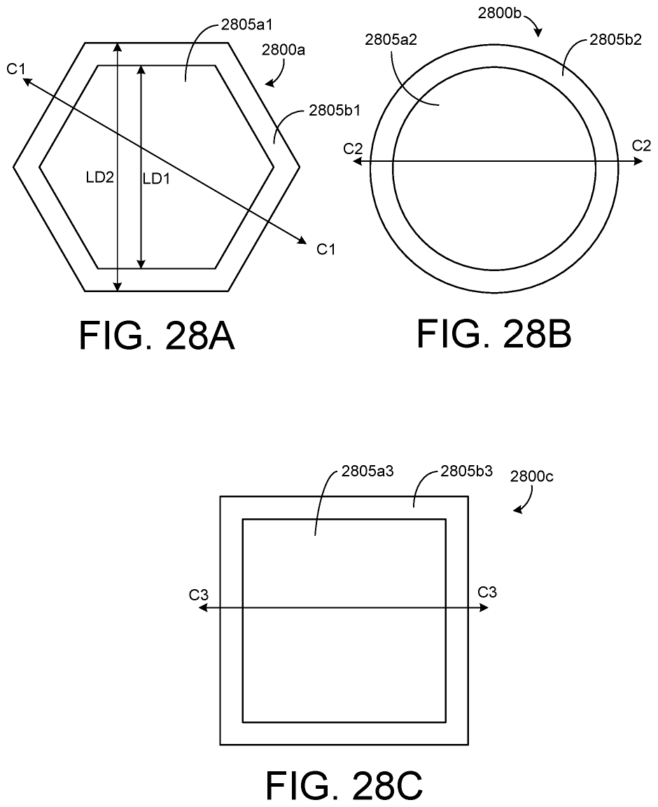

FIGS. 1 to 9 are diagrams that illustrate example implementations of uLEDs (uLED mesas) that can be produced and electrically operated using the approaches described herein. The examples of FIGS. 1 to 9 illustrate cross-sectional views of uLEDs, such as along cross-sectional lines of the example uLED mesas of FIGS. 28A to 28C. The uLED mesas of the examples of FIGS. 1 to 9, as with the examples of FIGS. 28A to 28C, can be implemented using a number of mesa shapes, such as hexagonal, circular, or square. In other implementations, a uLED mesa can have other shapes, such as a triangle, or a rectangle, for example. That is, a perimeter of a uLED mesa (e.g., its base and upper surface) can be shaped based on the particular implementation.

In each of FIGS. 1 to 9, a line H indicates a horizontal (lateral) direction, while a line V indicates a vertical direction, in accordance with use of those terms herein. As noted above, the vertical direction is parallel with a direction of epitaxial layer growth for epitaxial layers used to form the respective uLEDs, while the horizontal (lateral) direction is perpendicular to the epitaxial growth direction. For purposes of brevity, as there are number of similar structural and operational aspects of the examples of FIGS. 1 to 9, details discussed with respect to one example implementation may not be discussed with respect to similar aspects of other implementations.

FIG. 1 illustrates an example implementation of a uLED 100 that can be produced and electrically operated in accordance with the approaches and techniques described herein. As shown in FIG. 1, a uLED mesa 105 can be produced on a growth interface 110, e.g., using epitaxial layer regrowth processes. The growth interface 110 can be a surface of a substrate, such as silicon, GaN, sapphire, etc. After forming the uLED mesa 105, in the example of FIG. 1, a growth template 115 (growth mask) for producing the uLED mesa 105 can be formed on the growth interface 110. In some implementations, the growth template 115 can be a silicon dioxide (SiO₂) growth mask, in which an opening is defined using photolithography operations to expose the growth interface 110.

After forming the growth template 115, the uLED mesa 105 can be selectively grown in the opening using epitaxial regrowth process operations, where the composition of the epitaxial layers is modified during growth of the uLED mesa 105 to produce different portions (layers) of the uLED mesa 105. For instance, an n-type region 120 can be formed, followed by an active region 130 (which can also be referred to as a multiple QW region, or MQW region), and then a p-type layer 125 can be formed. As shown in FIG. 1, the uLED mesa 105 can have slanted sidewalls 105b, where the slanted sidewalls 105b are non-horizontal and non-vertical. That is, the slanted sidewalls 105b can be arranged along respective semi-polar planes of a crystalline structure (e.g., GaN) of the uLED mesa 105. The slanted sidewalls may also have a more complex shape than a planar facet, for instance having a non-constant angle.

The active region 130 of the uLED mesa 105 includes a QW 130a, a QW 130b, and QW 130c and a QW 130d. While the uLED 100 is shown as including four QWs, in other implementations, a different number of QWs can be included, such as three, five, seven, ten, and so forth. In this example, the QWs 130a-130d and the p-type layer 125 are grown both along an upper portion 105a of the uLED mesa 105 and along the slanted sidewalls 105b of the uLED mesa 105. The QWs 130a-130d can be considered as portions, such as a planar portion arranged the horizontal direction, and slanted portions arranged along non-horizontal and non-vertical planes. As shown in FIG. 1, the planar portions of the QWs are respectively connected to the slanted portions of the QWs in a one-to-one relationship.

In the uLED 100, an electrical contact 135, such as a p-type contact can be formed on (disposed on) the p-type layer 125. In example implementations, the electrical contact 135 can be formed using a metal layer, such as silver, platinum, titanium, nickel, and/or tungsten, as some examples. Upon electrical operation of the uLED 100, as illustrated by the arrows 140 in FIG. 1, holes are injected from the electrical contact 135 at both the upper portion 105a and the slanted sidewalls 105b of the uLED mesa 105, and then injected into the QWs 130a-130d. In this example, lateral hole injection, e.g., from holes injected into the slanted sidewalls 105b, can occur in all the QWs 130a-130b (though only specifically illustrated for the QW 130a and the QW 130d). The holes injected from the sidewalls can then diffuse laterally inside the QWs 130a-130d (e.g., over a corresponding diffusion length L), which can lead to a substantial hole density, e.g., of at least 5e17/cm³, in each of the QWs 130a-130d. That is, the sidewall injected holes can be injected approximately evenly, or distributed approximately equally, e.g., by percentage, over the QWs 130a-130d.

In some examples, the QWs 130a-130d of the active region 130 (the MQW region) can be undoped (e.g., undoped GaN), n-doped (e.g., n-doped GaN), or lightly p-doped (p-doped GaN) as compared to a doping concentration of the p-type layer 125. A region of the uLED mesa 105 where lateral injection of holes occurs may correspond with a lateral p-n junction of the uLED mesa 105, and the slanted portions of the QWs 130a-130b may be positioned in a depletion region of that lateral p-n junction.

FIG. 2 is a diagram illustrating an example of another implementation of a uLED 200. The uLED 200 is a variation of the uLED 100 of FIG. 1. In this example, a uLED mesa 205 is regrown on a growth interface 210 using a growth template 215 (e.g., a SiO₂ mask). As compared to the uLED mesa 105 of FIG. 1, growth of slanted regions 205b (slanted sidewalls) of the uLED mesa 205 occurs laterally, and on an upper surface of the growth template 215. Different epitaxial regrowth process conditions can be used to produce the uLED mesa 205 as compared to regrowth process conditions used to produce the uLED mesa 105.

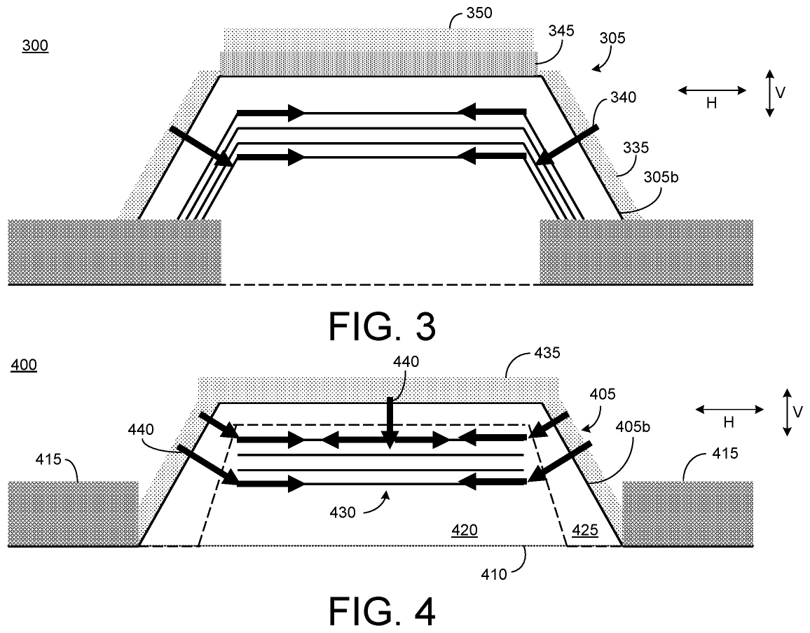

FIG. 3 is a diagram illustrating an example of another implementation of a uLED 300. The uLED 300 is a variation of the uLED 200 of FIG. 2. In this example, electrical contacts 335 are formed only on the slanted sidewalls 305b of a uLED mesa 305, e.g., not on an upper surface of the uLED mesa 305. As shown in FIG. 3, an insulating material 345, e.g., a transparent insulating material, is disposed on an upper surface of a p-type layer 325 of the uLED mesa 305, and a mirror 350 is disposed on the insulating material 345. In this example, the mirror 350 can improve emission of light, e.g., from a bottom side of the uLED mesa 305, as shown in FIG. 3. In example implementations, materials included in the electrical contacts 335 (p-type contacts) can be selected for both electrical conductivity and reflectivity, while materials included in the mirror 350 can be selected only for reflectivity. In some implementations, the mirror 350 can include silver (Ag).

In the example of FIG. 3, the electrical contacts 335 are illustrated as being separate from the mirror 350. However, in some implementations, the electrical contacts 335 and the mirror 350 can be implemented using a single metal layer, which can function as both the electrical contacts 335 and the mirror 350.

FIG. 4 is a diagram illustrating an example of another implementation of a uLED 400. The uLED 400 is a variation of the uLED 100 of FIG. 1. In the example of FIG. 4, the uLED 400 includes a uLED mesa 405 that can be regrown on a growth interface 410 using a growth template 415. In his example, as compared to the uLED mesa 105, the uLED mesa 405 includes an MQW region 430 where QWs of the MQW region 430 are not grown (not present) along lateral facets of the uLED mesa 405. The MQW region 430 can be referred to as a planar MQW region. That is the QWs of the MQW region 430 do not have slanted portions that extend along the slanted sidewalls 405b, e.g., the QWs only extend in the horizontal direction.

Accordingly, the slanted sidewalls 405b, in this example, include either lateral p-n junctions, or lateral p-i-n junctions that inject carriers (e.g., holes) received from a contact 435 into the QWs of the MQW region 430. For instance, a p-type layer 425 and an n-type region 420 can define the lateral p-n or p-i-n junctions, where the dashed in FIG. 4 indicates an approximate boundary of the p-type layer 425, which will depend on the change of epitaxial composition during regrowth of the uLED mesa 405.

The p-type layer 425, in the uLED mesa 405, is also present along a top surface of the uLED mesa 405, and can form a planar p-n junction or planar p-i-n junction along a top facet of the uLED mesa 405. In example implementations, carriers injected (e.g., laterally injected) from the p-type layer 425 into the QWs of the MQW region 430 can then diffuse laterally over a corresponding diffusion length L in the QWs of the MQW region 430, such as shown by the arrows 440 in FIG. 4 illustrating hole flow in the uLED 400. In some implementations, injected carriers (e.g., holes) from the p-type layer 425 may also diffuse laterally in other layers of the uLED mesa 405.

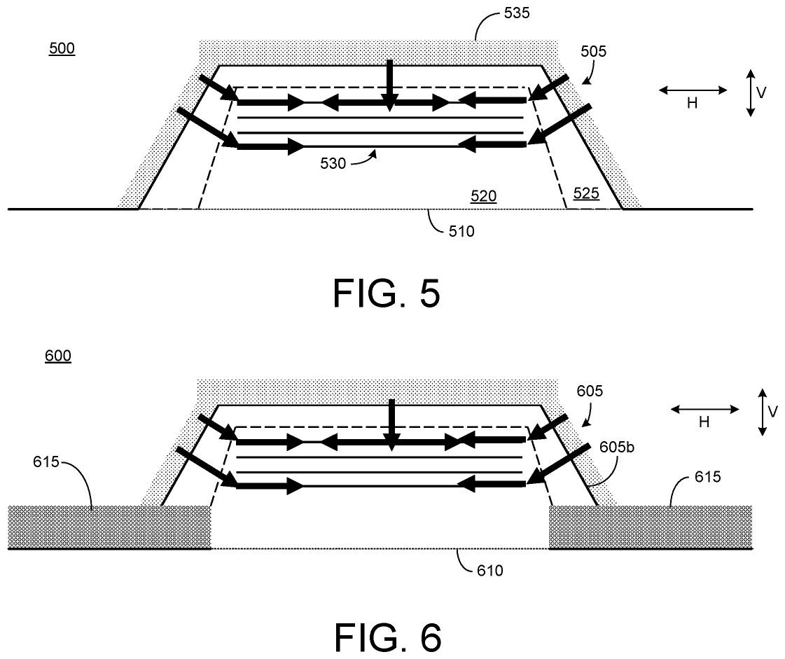

FIG. 5 is a diagram illustrating an example of another implementation of a uLED 500. The uLED 500 is a variation of the uLED 400 of FIG. 4. In the example of FIG. 5, the uLED 500 includes a uLED mesa 505 that can be produced on a growth interface 510 without using a growth template, e.g., using regrowth and other processing techniques, such as anisotropic etching. As with uLED 400, the uLED mesa 505 includes an n-type region 520, a MQW region 530, a p-type layer 525, and a contact 535 that can operate similar to the corresponding elements of the uLED 400.

FIG. 6 is a diagram illustrating an example of another implementation of a uLED 600. The uLED 600 is also a variation of the uLED 400 of FIG. 1. In this example, a uLED mesa 605 is regrown on a growth interface 610 using a growth template 615 (e.g., a SiO₂ mask). As compared to the uLED mesa 405 of FIG. 4, growth of slanted regions 605b (slanted sidewalls) of the uLED mesa 605 occurs laterally, and on an upper surface of the growth template 615. As with the examples of FIGS. 1 and 2, different epitaxial regrowth process conditions can be used to produce the uLED mesa 605 as compared to regrowth process conditions used to produce the uLED mesa 405.

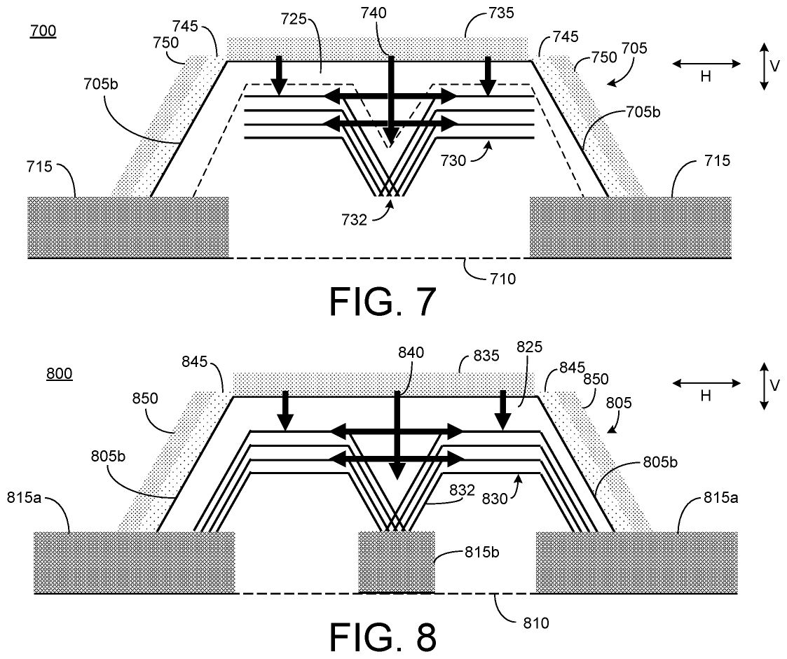

FIG. 7 is a diagram illustrating an example of another implementation of a uLED 700. As shown in FIG. 7, a uLED mesa 705 of the uLED 700 can be grown on a growth interface 710 using a growth template 715. The uLED mesa 705 includes a MQW region 730 that includes a slanted region 732 located in the center of the uLED mesa 705 (e.g., horizontally centered). In some examples, the slanted region 732 can be formed by defining a V-shaped pit in the uLED mesa 705 during epitaxial regrowth. A p-type layer 725 (e.g., p-type GaN) can then be formed, and the p-type layer 725 can be planarized to define a horizontal facet of the uLED mesa 705.

In this example, a contact 735 (p-type contact) is disposed on the horizontal facet of the uLED mesa 705. An insulating material 745 (a transparent insulating material) is disposed on slanted sidewalls 705b of the uLED mesa 705, and mirrors 750 are disposed on the insulating material 745. Accordingly, in this example, as is shown by the arrows 740 in FIG. 7, holes can be vertically injected into the p-type layer 725 and then laterally injected into the QWs of the

MQW region 730 in the slanted region 732. Accordingly, lateral injection from p-material to the QWs may occur from a peripheral portion of the mesa and/or from an inner portion of the mesa.

FIG. 8 is a diagram illustrating an example of another implementation of a uLED 800. As shown in FIG. 8, a uLED mesa 805 of the uLED 800 can be grown on a growth interface 810 using a growth template that includes a first masked region 815a, and a second masked region 815b that is located in the center of the growth interface 810. In this example, during regrowth, epitaxial layers grown on the second masked region 815b can have inclined lateral sidewalls on which a slanted portion 832 of a MQW region 830 is defined. As with the uLED 700, a p-type layer 825 (e.g., p-type GaN) can then be formed (e.g., over the MQW region 830), where the p-type layer 825 can be planarized to define a horizontal facet of the uLED mesa 805.

In this example, similar to the uLED 700, a contact 835 (p-type contact) is disposed on the horizontal facet of the uLED mesa 805. An insulating material 845 (a transparent insulating material) is disposed on slanted sidewalls 805b of the uLED mesa 805, and mirrors 850 are disposed on the insulating material 845. Accordingly, in this example, as is shown by the arrows 840 in FIG. 8, holes can be vertically injected into the p-type layer 825 and then laterally injected into the QWs of the MQW region 830 in the slanted portion 832.

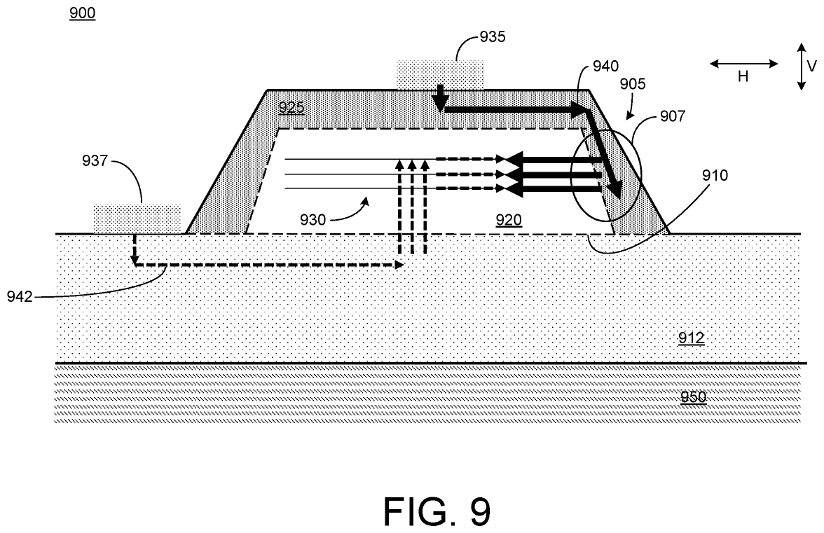

FIG. 9 is a diagram illustrating an example of another implementation of a uLED 900. The uLED 900 is similar to the uLED 500. For instance, the uLED 900 includes a uLED mesa 905 that is formed on a growth interface 910. The uLED mesa 905 can include an n-type region 920, a MQW region 930, a p-type layer 925, and a contact 935 (p-type contact) that is disposed on an upper (horizontal) facet of the uLED mesa 905. As also shown in FIG. 9, a contact 937 (n-type contact) can be disposed on an n-doped buffer 912 (which can also be referred to as a template) that electrically couples the n-type region 920 with the contact 937.

In example implementations, the growth interface 910 can be a surface of the n-doped buffer 912. The n-doped buffer 912 is formed on a substrate 950. The substrate 950 can include, as some examples, sapphire, silicon, silicon carbide (SiC), bulk GaN, or bulk aluminum nitride (AlN), e.g., for III-nitride LEDs. The n-doped buffer 912 can be an n-doped semiconductor material, such as n-type GaN. In some implementations, an electrical connection (e.g., contact) to the n-type region 920 can be made in other ways than as shown in FIG. 9.

In some implementations, after forming the uLED 900, the substrate 950 may be removed using one or more process operations, such as grinding, etching, and/or lift-off operations. The n-doped buffer 912, or a portion thereof, may also be removed or thinned. In some cases, the contact 935 can be reflective, and the uLED 900 can emit light towards (from) the n-type region 920 (e.g., either through a transparent substrate, or after substrate removal). For instance, the uLED 900 can be implemented in a flip-chip device.

FIG. 9 illustrates an example of how carrier injection can occur in the uLED 900, as well as in the uLEDs of other example implementations described herein. In FIG. 9, the arrows 940 illustrate the flow of holes in the uLED 900, while the arrows 942 illustrate the flow of electrons in the uLED 900. As shown by the arrows 940, holes are injected from the contact 935 to the p-type layer 925. In some implementations, the p-type layer 925 can include p-type GaN-based layers, as well as other layers. For instance, in some implementations, the p-type layer 925 can include a p-type AlGaN layer, which can function as an electron-blocking layer.

As shown by the arrows 940 in FIG. 9, the injected holes are then conducted through the semiconductor p-layer and reach a lateral injection region 907, e.g., where the p-type layer 925 layer is located next to QWs of the MQW region 930 along a lateral (horizontal) direction. The holes, after reaching the lateral injection region 907, are injected laterally from the p-type layer 925 into the QWs of the MQW region 930. The lateral injection region 907 and the MQW region 930 can be configured, using the approaches described herein, such that substantial hole injection occurs into each QW of the MQW region 930. For instance, as shown in FIG. 9, three QWs are injected and, in this example, each QW receives a similar hole current. In other implements, a different number of QWs can be injected, such as five, seven, ten, etc. In the example of FIG. 9, the holes injected into the QWs of the MQW region 930 then diffuse laterally in the QW (over a corresponding diffusion length L), which can result in a substantial hole density across the QWs. For instance, in such implementations, a hole density can be substantially constant across each of the QWs during operation of the uLED 900.

As shown by the arrows 942 in FIG. 9, electrons are injected from the contact 937 into the n-doped buffer 912, and then diffuse laterally (e.g., in the horizontal direction). The electrons, shown by the arrows 942, can then be injected in the vertical direction from n-doped buffer 912, through the n-type region 920 and into the QWs of the MQW region 930. As shown in FIG. 9, electrons can be injected into each QW of the MQW region 930 into which holes are injected. The electrons, after being injected into the QWs of the MQW region 930 can then diffuse laterally in the QWs. The injected holes and injected electrons can then meet in the QWs of the MQW region 930, and recombine to emit light.

In some implementations, the region surrounding the MQW region 930 (e.g., the n-type region 920 in FIG. 9) can be n-type doped, or nominally undoped (relative to other regions of the uLED 900). In other implementations, the region surrounding the MQW region 930 can be lightly n-doped or p-doped, e.g., with a doping concentration that is at least one order of magnitude less than a typical carrier density in the QWs of the MQW region 930 during operation. For instance, in some implementations, the QWs of the MQW region 930 can operate with a carrier density of at least 1E18/cm³, and a doping concentration of the region surrounding the MQW region 930 can be less than or equal to 1E17/cm³.

As illustrated by the example implementations of FIGS. 1 to 9, depending on the configuration of a μLED (LED), including its epitaxial layers and electrical contacts, injection of holes from a p-contact to a p-layer (e.g. p-type GaN layer) can occur substantially, or only, in a specific region of a device. For instance, hole injection can occur only at a slanted sidewall, or only on a top portion (horizontal facet) of the μLED. Injection of holes from the p-layer to QWs can occur both from the top facet and slanted sidewalls, mostly from the slanted sidewalls, or only from the slanted sidewalls.

For instance in some implementations, a contact can be formed on (disposed on) at least a portion of a slanted sidewall, and holes can be injected from the sidewall contact to sidewall p-type GaN, without hole injection occurring on the top facet of the μLED. The holes can then be laterally injected into the QWs. In other implementations, a contact can be formed on (disposed on) at least a portion of a top, or horizontal facet of a μLED, and holes can be injected from the contact to top p-type GaN, conducted from the top p-type GaN to sidewall p-type GaN, and then injected from the sidewall p-type GaN laterally into the QWs (e.g., either slanted portions of QWs, or QWs of a planar MQW). Other example implementations can have variations in contact geometry. For instance, a lateral contact can be disposed (formed) only on a portion of the lateral, slanted sidewall, while other portions of the lateral, slanted sidewall can be covered by an insulating layer to electrical contact prevent contact.

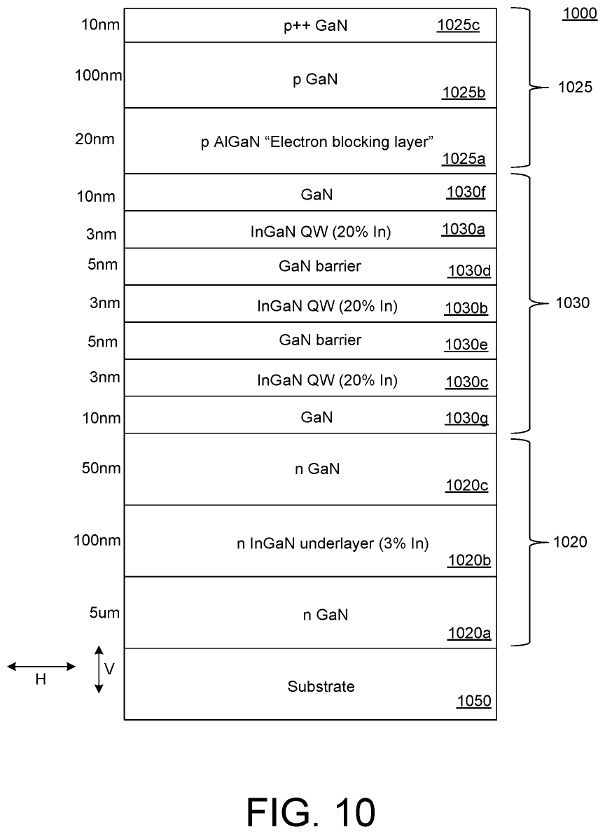

FIG. 10 is a diagram schematically illustrating an example epitaxial layer stack 1000 that can be included in μLED, such as the μLEDs of FIGS. 1-9. The epitaxial layer stack 1000 is shown by way of example, and for purposes of illustration, and the specific epitaxial layers included in a μLED, as well as their thicknesses, and composition will depend on the particular implementation.

Also, for purposes of illustration, the epitaxial layer stack 1000 is shown in a vertically stacked arrangement. In some implementations, such as the examples of FIGS. 1 to 9, one or more portions of the epitaxial layer stack 1000 can also be included in slanted portions of a μLED mesa (e.g., QWs and/or p-type layers), e.g., to defined slanted, or slope sidewalls.

As shown in FIG. 10, the epitaxial layer stack 1000 can be formed on a substrate 1050, which provides a growth interface. The epitaxial layer stack 1000, in this example, includes an n-type region 1020 that is disposed on the substrate 1050. In this example, the n-type region 1020 includes a n-type GaN layer 1020a with a thickness of 5 μm (which can also be referred to as also called a GaN buffer or template) that is disposed on the substrate 1050. The n-type region 1020 further includes a n-type InGaN underlayer 1020b with a thickness of 100 nm and three-percent In composition that is disposed on the n-type GaN layer 1020a. The n-type region 1020 also includes a n-type GaN layer 1020c with a thickness of 50 nm is disposed on the n-type InGaN underlayer 1020b.

In the example of FIG. 10, the epitaxial layer stack 1000 further includes a MQW region 1030 (active region) that is disposed on the n-type region 1020. The MQW region 1030 of the epitaxial layer stack 1000 includes a QW 1030a, a QW 1030b, and a QW 1030c. The QWs 1030a-1030c each have a thickness of 3 nm and a twenty-percent In composition in this example. The MQW region 1030 also includes a GaN barrier layer 1030d (e.g., undoped GaN) with a thickness of 5 nm that is disposed between the QW 1030a and the QW 1030b, and a GaN barrier layer 1030e (e.g., undoped GaN) with a thickness of 5 nm that is disposed between the QW 1030b and the QW 1030c. In this example, the MQW region 1030 further includes a GaN layer 1030f and a GaN layer 1030g (e.g., undoped GaN), which each have a thickness of 10 nm. The GaN layer 1030f is disposed between the QW 1030a and a p-type region 1025. The GaN layer 1030g is disposed between the QW 1030c and the n-type region 1020.

As further shown in FIG. 10, p-type region 1025 of the epitaxial layer stack 1000 includes a p-type AlGaN layer 1025a (e.g., an EBL layer) with a thickness of 20 nm that is disposed on the GaN layer 1030f. The p-type region 1025 also includes a p-type GaN layer 1025b with a thickness of 100 nm that is disposed on the p-type AlGaN layer 1025a, and a heavily doped p-type GaN layer 1025c (e.g., a p++ GaN layer) with a thickness of 10 nm that is disposed on the p-type GaN layer 1025b. In example implementations, the heavily doped p-type GaN layer 1025c can facilitate formation of low resistance contacts (Ohmic contacts) to the p-type region 1025.

As described herein, and as noted above, in some implementations the MQW region 1030 and/or the p-type region 1025 can also be extended into slanted portions (e.g., slanted sidewalls) of a corresponding μLED. In some implementations, layers of the MQW region 1030 and p-type region 1025 may have different thicknesses and/or composition in the slanted portions, e.g., as compared to a planar portion of a corresponding μLED.

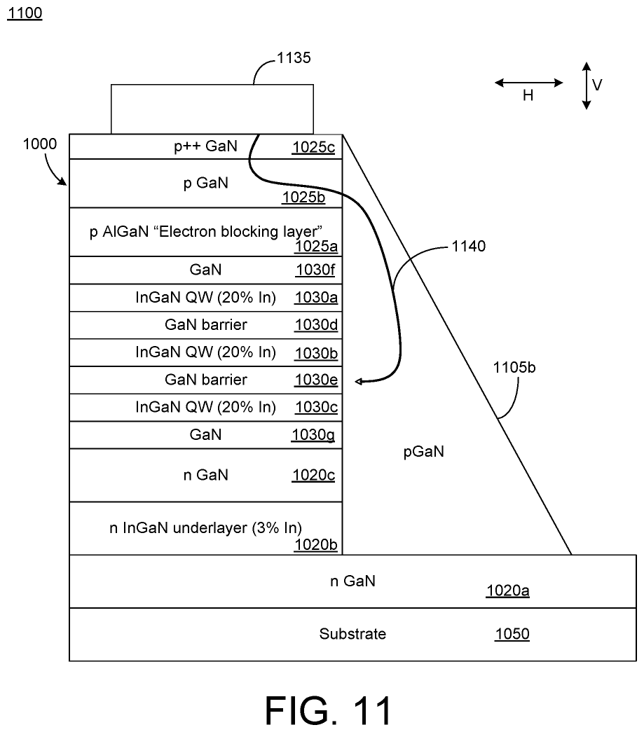

FIG. 11 is a diagram that schematically illustrates a portion of a μLED 1100. In this example, the LED 1100 is illustrated as including the epitaxial layer stack 1000 of FIG. 10. As shown in FIG. 11, p-type GaN material 1105 (e.g., which can be of like composition as the p-type GaN layer 1025b) is disposed horizontally (laterally) adjacent to the epitaxial layer stack 1000. The p-type GaN material 1105 defines a slanted sidewall 1105b of the LED 1100. As also shown in FIG. 11, a contact 1135 (p-type contact) is disposed on top surface of the heavily doped p-type GaN layer 1025c, which can correspond to an upper, horizontal facet of the LED 1100. As shown by the arrows 1140 in FIG. 11, holes can be injected from the contact 1135 into the heavily doped p-type GaN layer 1025c and the p-type GaN layer 1025b. The injected holes can then flow into the p-type GaN material 1105 from the heavily doped p-type GaN layer 1025c and the p-type GaN layer 1025b, where the holes can then be laterally injected from the p-type GaN material 1105 into the QWs 1030a-1030c.

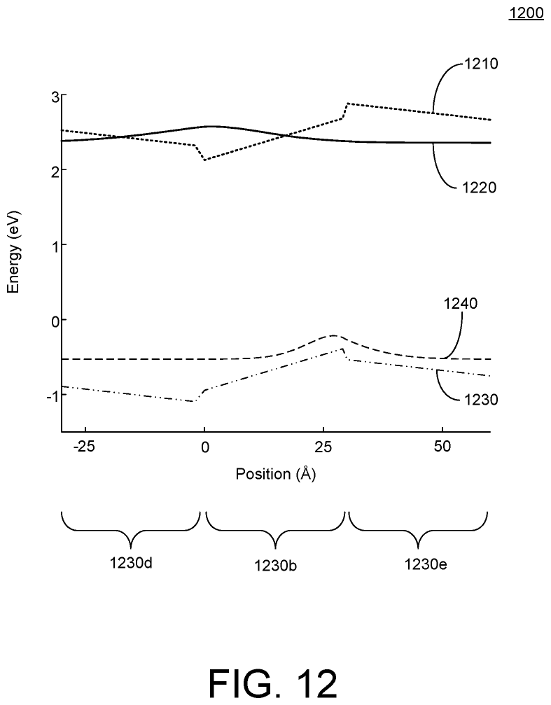

FIGS. 12, 13A-13D, and 14A-14D are graphs that illustrate modeling results demonstrating how varying thickness and/or In composition percentage in epitaxial layers included in a μLED (e.g., of QW layers) can be utilized to achieve a desired carrier lifetime, and a desired carrier diffusion length in a QW. Referring to FIG. 12, general structure of the model corresponding FIGS. 12, 13A-13D, and 14A-14D is illustrated. As shown in FIG. 12, in the example model, a QW 1230b is disposed between a first barrier layer 1230d and a second barrier layer 1230e. In this example, the QW 1230b, the first barrier layer 1230d and the second barrier layer 1230e can correspond respectively with the QW 1030b, the GaN barrier layer 1030d, the GaN barrier layer 1030e of the epitaxial layer stack 1000 of FIGS. 10 and 11. FIG. 12 also shows example plots of conduction band energies 1210, electron wavefunction 1220, valence band energies 1230, and hole wavefunction 1240, versus position (in angstroms as indicated on the x-axis) in the first barrier layer 1230d, the QW 1230b, and the second barrier layer 1230e. Energies for the illustrated example are indicated on the y-axis in FIG. 12 in electron-volts (eV).

For each QW configuration modeled, a corresponding electron wavefunction (e.g., electron wavefunction 1220) and hole wavefunction (e.g., wavefunction 1240) are computed by solving Schrodinger's equation. A corresponding oscillator strength O (e.g., equal to the squared overlap integral between the electron and hole wavefunctions) is then computed. Respective recombination coefficients are then computed, e.g., based on an empirical relationship between O and corresponding recombination coefficients (e.g., such as the coefficients discussed above) are determined, e.g., as B=O*B₀, A=O\hat{ }0.8*A₀, C=O\hat{ }1.2*C₀, where A₀, B₀, and C₀ are bulk-like coefficients (without quantum confinement effects) for the SRH, radiative and Auger rates. Respective carrier lifetime can then be given by 1/tau=A+2Bn+3Cn², and the diffusion length L can be given by L=sqrt(D*tau), with D=2 cm²/s, which can be a nominal diffusion coefficient value for InGaN QWs. While operation of physical devices can depart from this model, the model provides guidance on the relationship between QW configuration (e.g., thickness and/or In percent composition) and diffusion length.

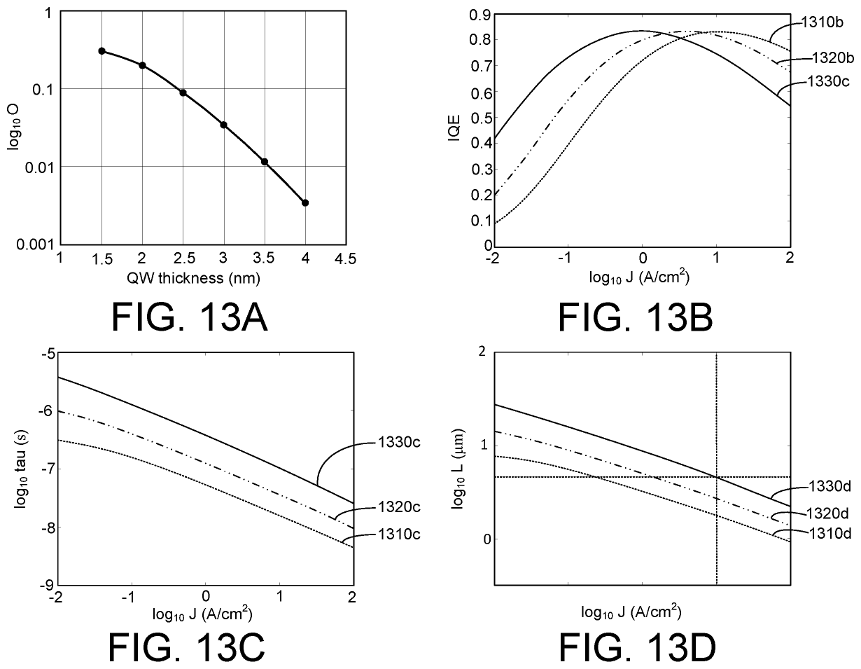

FIGS. 13A-13D are graphs illustrating how varying a thickness of the QW 1230b (e.g., of the model illustrated in FIG. 12) at a fixed fifteen-percent In composition affects oscillator strength O, internal quantum efficiency (IQE), carrier lifetime (tau), carrier diffusion length (L) of the QW 1230b. For instance, FIG. 13A is a graph that illustrates oscillator strength on a log₁₀ scale versus QW thickness (in nm). As can be seen in FIG. 13A, as QW thickness increases, O decreases.

FIG. 13B is a graph that illustrates IQE (with percent IQE shown as decimal values) versus current density, on a log₁₀ scale, for different QW thicknesses. Specifically, FIG. 13B illustrates modeling results for QW thicknesses of 2 nm (curve 1310b), 3 nm (curve 1320b), and 4 nm (curve 1330c). As can be seen in FIG. 13B, as QW thickness increases, the peak IQE shifts to lower current density (with the peak at each thickness being approximately equal).

FIG. 13C is a graph that illustrates carrier lifetime tau on a log₁₀ scale versus current density on a log₁₀ scale for the same QW thicknesses as FIG. 13B. That is, FIG. 13C illustrates modeling results for QW thicknesses of 2 nm (curve 1310c), 3 nm (curve 1320c), and 4 nm (curve 1330c). As can be seen in FIG. 13C, as QW thickness increases, carrier lifetime, for a same current density, increases.

FIG. 13D is a graph that illustrates diffusion length L on a log₁₀ scale versus current density on a log₁₀ scale for the same QW thicknesses as FIGS. 13B and 13C. That is, FIG. 13D illustrates modeling results for QW thicknesses of 2 nm (curve 1310d), 3 nm (curve 1320d), and 4 nm (curve 1330d). As can be seen in FIG. 13D, as QW thickness increases, diffusion length, for a same current density, increases. As shown by the modeling results of FIGS. 13A-13D, by varying the thickness of a QW with a fixed percentage In composition, a desired diffusion length can be achieved. For instance, as shown by the modeling results of FIGS. 13A-13D, at a current density J=10 A/cm² a diffusion length L=5 um can be achieved for a QW with a thickness of 4 nm and fifteen percent In composition.

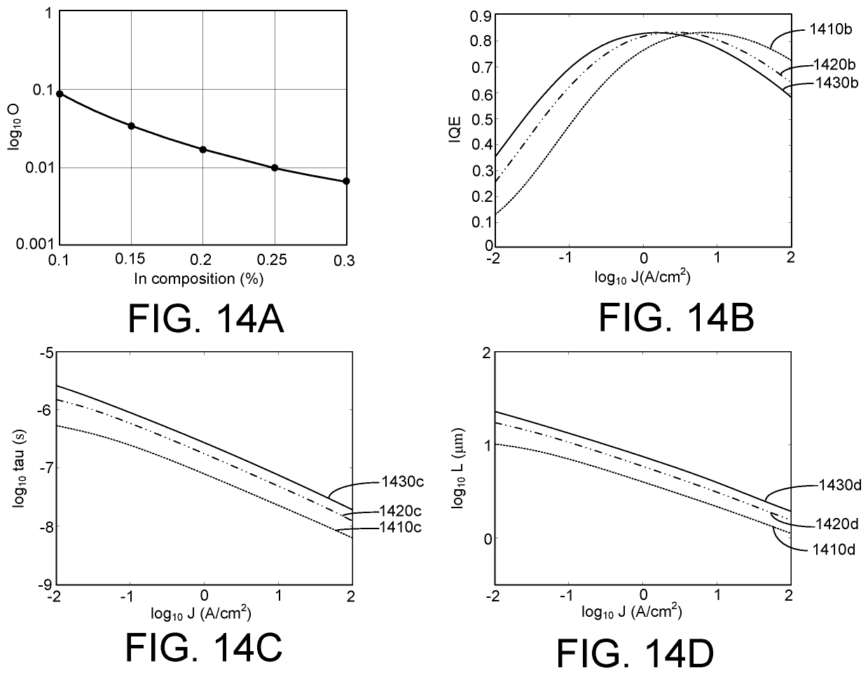

FIGS. 14A-14D are graphs illustrating how varying an In composition percentage of the QW 1230b (e.g., of the model illustrated in FIG. 12) at a fixed QW thickness of 3 nm affects oscillator strength, internal quantum efficiency (IQE), carrier lifetime (tau), carrier diffusion length (L) of the QW 1230b. FIG. 14A is a graph that illustrates oscillator strength on a log₁₀ scale versus QW In composition percentage. As can be seen in FIG. 14A, as In composition percentage increases, O decreases.

FIG. 14B is a graph that illustrates IQE (with percent efficiency shown as decimal values) versus current density, on a log₁₀ scale, for different In composition percentages. Specifically, FIG. 14B illustrates modeling results for QW In composition percentages of 10% (curve 1410b), 20% (curve 1420b) and 30% (curve 1430b). As can be seen in FIG. 14B, as In composition percentage increases, the peak IQE shifts to lower current density (with the peak at each In composition percentage being approximately equal).

FIG. 14C is a graph that illustrates carrier lifetime tau on a log₁₀ scale versus current density on a log₁₀ scale for the same In composition percentages as FIG. 14B. That is, FIG. 14C illustrates modeling results for In composition percentages of 10% (curve 1410c), 20% (curve 1420c), and 30% (curve 1430c). As can be seen in FIG. 14C, as In composition percentage increases, carrier lifetime, for a same current density, increases.

FIG. 14D is a graph that illustrates diffusion length L on a log₁₀ scale versus current density on a log₁₀ scale for the same In composition percentages as FIGS. 14B and 14C. That is, FIG. 14D illustrates modeling results for In composition percentages of 10% (curve 1410d), 20% (curve 1420d), and 30% (curve 1430d). As can be seen in FIG. 14D, as In composition percentage increases, diffusion length, for a same current density, increases. As shown by the modeling results of FIGS. 14A-14D, by varying the In composition percentage a QW with a fixed thickness, a desired diffusion length can be achieved. For instance, as shown by the modeling results of FIGS. 14A-14D, at a current density J=10 A/cm² a diffusion length L=3.5 um can be achieved for a QW with a thickness of 3 nm and an In composition of 30%.

In a general aspect, epitaxial layers of a μLED in an active region can be configured, e.g., including QW layers' and barrier layers' composition, thickness, doping, level of disorder, such that an electrostatic structure and density of states in the active region can be achieved, which results in a desired carrier lifetime and desired diffusion length at a desired (e.g., predetermined) operating current density for the μLED. In some implementations, a desired wavelength of emitted light, a desired IQE, and other performance properties of QWs of a μLED can be achieved. That is, in some implementation, an epitaxial structure of a μLED active region can be produced to achieve a desired wavelength for emitted light, a desired diffusion length for carriers injected into QWs of an active region of the μLED, and a desired IQE, at an operating current density J. In some implementations, a diffusion length of at least 1 um, at least 2 um, or at least 3 um can be achieved, and a corresponding IQE of at least 20%, at least 30%, or at least 40%, at an operating current density J of 1 A/cm2, 5 A/cm2, 10 A/cm2, 50 A/cm2, or 100 A/cm2, can be achieved.

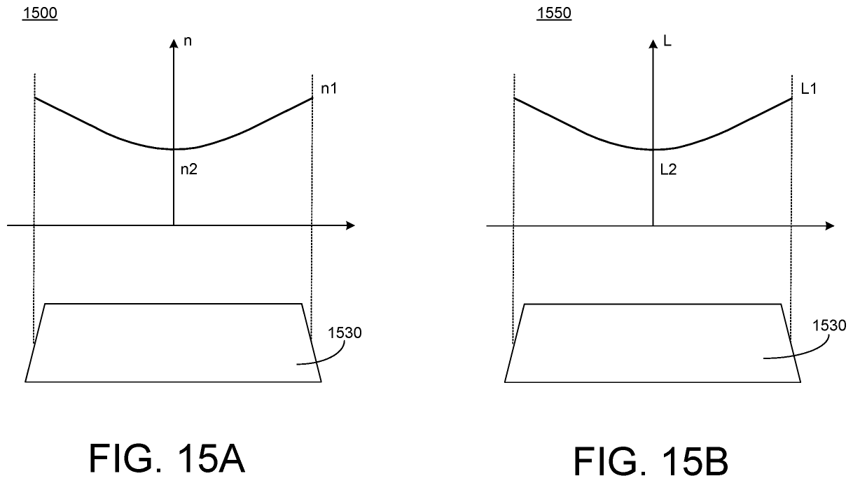

As discussed above, using the approaches described herein, LEDs (μLEDs) can be produced and operated with improved performance as compared to prior LED implementations. For instance, example μLED implementations described herein can operate with improved carry distribution and, as result, improved light output and distribution. FIGS. 15A and 15B are diagrams that schematically illustrate, respectively, a carrier distribution and a light emission (output) distribution for μLEDs implementations, such as those described with respect to FIGS. 1-9.

FIG. 15A schematically illustrates lateral (horizontal) distribution of carrier density inside a QW 1530 of a uLED mesa, e.g., during electrical current injection (and emission of light). The QW 1530 may be one of several QWs, such as a planar portion of a QW included in a MQW region. As shown in FIG. 15A, the carrier density n (as indicated on the y-axis) has a value n1 at the edges (e.g., left and right slanted sidewalls) of a uLED in which the QW 1530 is included (e.g., where hole injection occurs). Using the approaches described herein to achieve a desired diffusion length for lateral carrier diffusion in the QW 1530, the carrier density distribution of FIG. 15A has a carrier density value n2 at a center of the QW 1530, where the ratio of n2 to n1 can be at least 30%, at least 50%, or at least 70%. In some implementations, such as those described here, this carrier density ratio can apply to each of the QWs in a corresponding MQW region. For instance, such current density ratios can apply for least 2 QWs, at least 3 QWs, or at least 5 QWs (or 3, 4, 5) in a MQW region.

Such carrier density distributions can, in turn, result in improved distribution of light output across an associated μLED or LED, e.g., from the QW 1530 and other QWs included in a corresponding μLED device. For instance, FIG. 15B schematically illustrates lateral (horizontal) distribution of the light output emitted from the top surface of the QW 1530 in this example, during electrical current injection and lateral diffusion in the QW 1530. As shown in FIG. 15B, the light output L (as indicated on the y-axis) has a value L1 at the edges (e.g., left and right slanted sidewalls) of a uLED in which the QW 1530 is included (e.g., where hole injection occurs). Using the approaches described herein to achieve a desired diffusion length for lateral carrier diffusion in the QW 1530, and the carrier density distribution of FIG. 15A, the light output L has a value L2 at a center of the QW 1530, where the ratio of L2 to L1 can be at least 30%, at least 50%, or at least 70%. In some implementations, such as those described here, this light output ratio can apply to QWs in corresponding MQW region. For instance, such light output ratios can apply for least 2 QWs, at least 3 QWs, or at least 5 QWs (or 3, 4, 5) in a MQW region. That is, in some implementation, injecting carriers into multiple quantum wells can facilitate better LED performance, including improved IQE and/or a preferred wavelength for light that is emitted at a predetermined operation current.

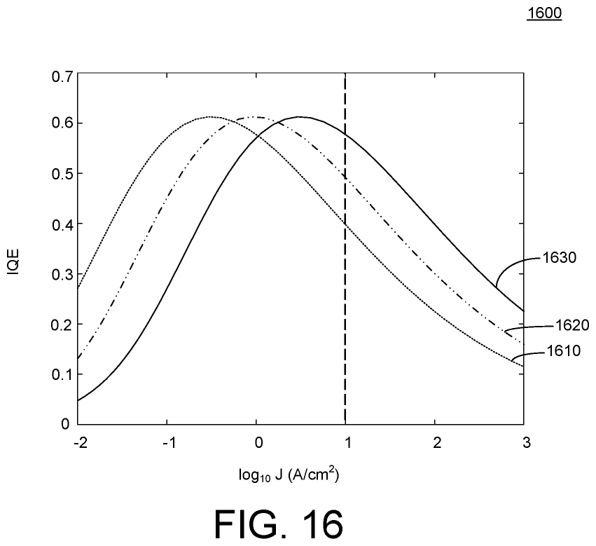

FIG. 16 is a graph 1600 illustrating a relationship (e.g., predicted from modeling) between current density, on a log₁₀ scale, and IQE (percentage indicated in decimal numbers) with a varying number N of QWs injected for μLEDs implementations, such as those described herein with respect to FIGS. 1-9. In the graph 1600, a curve 1610 corresponds to an implementation in which N=1 (only one QW is injected). In this example, the μLED reaches a peak IQE of 60% at a current density below 1 Acm2, and the IQE is reduced at higher current density. For instance, at J=10 A/cm², the IQE indicated by the curve 1610 is approximately 40%. In μLEDs implemented and operated using the approaches and techniques described here, lateral injection can allow for increasing N, which shifts the corresponding IQE curves to higher current densities. For instance, in the graph 1600, a curve 1620 corresponds with N=3, and a curve 1630 corresponds with N=10. With the assumption that there is approximately equal carrier injection in all QWs (3 for the curve 1620 and 10 for the curve 1630), the IQE, as shown in FIG. 16, increases with increasing N at a fixed current density J. For instance, at a current density J=10 A/cm², the IQE is approximately 50% for N=3, and approximately 55% for N=10. In such implementations, a measure of external quantum efficiency (EQE) and/or wall plug efficiency (WPE) for μLEDs with differing numbers of QWs injected may follow a similar trend as that shown for IQE in FIG. 16.

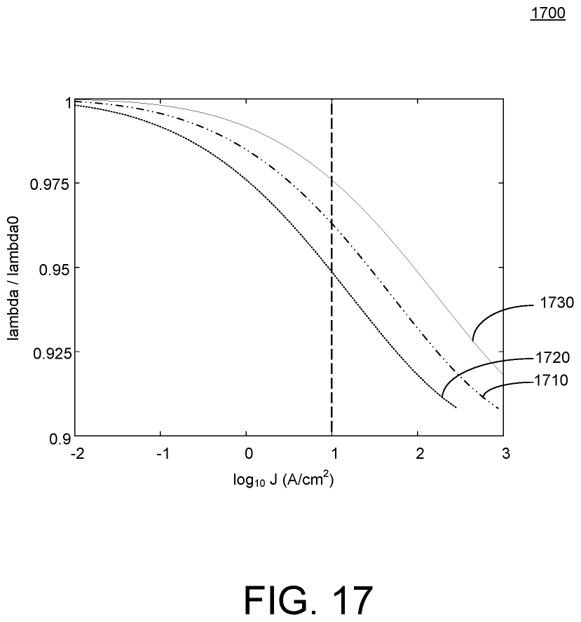

FIG. 17 is a graph 1700 illustrating a relationship (e.g., predicted from modeling) between current density, on a log₁₀ scale, and wavelength of emitted light with a varying number N of QWs injected for μLEDs implementations, such as those described herein with respect to FIGS. 1-9. In the graph 1700, normalized or relative wavelengths are illustrated. For instance, the normalized wavelengths illustrated by the graph 1700 are determined as lambda/lambda0 (indicated on the x-axis of the graph 1700). In this example, lambda is a centroid wavelength at a desired operating current density J, while lambda0 is a centroid wavelength at a comparatively low current density (e.g., a current density at which a wavelength plateau is observed). In the graph 1700, a curve 1710 illustrates relative (normalized) wavelength corresponding with a number N=1 of QWs injected, a curve 1720 illustrates relative (normalized) wavelength corresponding with a number N=3 of QWs injected, and a curve 1730 illustrates relative (normalized) wavelength corresponding with a number N=10 of QWs injected.

As can be seen in FIG. 17, wavelength of emitted light reaches a plateau at a low current density (e.g., approximately 0.1 A/cm²), and is reduced at higher current densities. For N=1 (one QW injected), as shown by the curve 1710, an onset of blue-shift of wavelength occurs at comparatively low current density. For instance, at a current density J=10 A/cm₂, the relative wavelength is less than 95%. That is, if lambda0 were 530 nm, lambda would be less than 505 nm. Such a blue-shift may not be desirable in some cases, e.g. if a longer wavelength of emitted light is desired.

In μLEDs implemented and operated using the approaches and techniques described here, lateral injection can allow for increasing N, which shifts the corresponding relative wavelength curves to higher current densities. As shown by the curve 1720 (N=3) and the curve 1730 (N=10), assuming approximately equal carrier injection in all injected QWs, the respective relative wavelengths are approximately 97% (for N=3) and above 97.5% (for N=10).

In some implementations, a μLED can have a number N of QWs (e.g., N is at least 3, at least 4, at least 5, at least 6, at least 7, at least 8, at least 9, or at least 10) that are substantially injected during electrical operation at a current density J, e.g., with J being at least 1 A/cm2, at least 5 A/cm2, at least 10 A/cm2, or at least 20 A/cm2. In some implementations, a μLED may have a peak wavelength of emitted light of at least 430 nm, at least 440 nm, at least 450 nm, at least 510 nm, at least 520 nm, at least 530 nm, at least 540 nm, at least 600 nm, at least 610 nm, or at least 620 nm when operated at a given current density J. That is, a μLED may have a peak wavelength of emitted light in a range of 430-480 nm, or 510-550 nm, of 600-650 nm. In some implementations, a μLED may have an operating IQE above 20%, above or 30%, above 40%, above 50%, or above 60%. In some implementations, a μLED may have an operating EQE above 5%, above 10%, above 15%, above 20%, above 25%, above 30%, above 35%, above 40%). In some implementations, a μLED may have an operating WPE above 5%, above 10%, above 15%, above 20%, above 25%, above 30%, above 35%, or above 40%.

In some implementations, a μLED may have a low-current centroid wavelength lambda0 (e.g., defined by a plateau of the wavelength at low current density) and an operating centroid wavelength lambda at a higher current density J, with the relative wavelength lambda/lambda0 being greater than 0.9, greater than 0.92, greater than 0.94, greater than 0.96, or greater than 0.98. In some implementations, a μLED can have a wavelength shift (lambda0-lambda) that is less than 50 nm, less than 30 nm, less than 20 nm, less than 15 nm, less than 10 nm, or less than 5 nm. In such implementations, lambda0 may be at least 450 nm, at least 470 nm, at least 490 nm, at least 550 nm, at least 570 nm, at least 620 nm, at least 630 nm, at least 640 nm, at least 650 nm, or at least 660 nm.

In some implementations, a μLED can have a reduced efficiency droop, or IQE droop, as compared to prior LED implementations. Such a reduction in IQE (efficiency) droop can be achieved as a result lateral injection approximately equally spreading injected carriers over a desired number of QWs. IQE droop can be defined as a relative value (a percentage), e.g., as an IQE at a given current density J divided by a peak IQE for a given μLED. In some implementations, a μLED can have an IQE droop that is greater than 50%, greater than 60%, greater than 70%, greater than 80%, or greater than 90%. In some implementations, a μLED can have an EQE droop that is greater than 50%, greater than 60%, greater than 70%, greater than 80%, or greater than 90%. In some implementations, a μLED can have a WPE droop that is greater than 50%, greater than 60%, greater than 70%, greater than 80%, or greater than 90%.

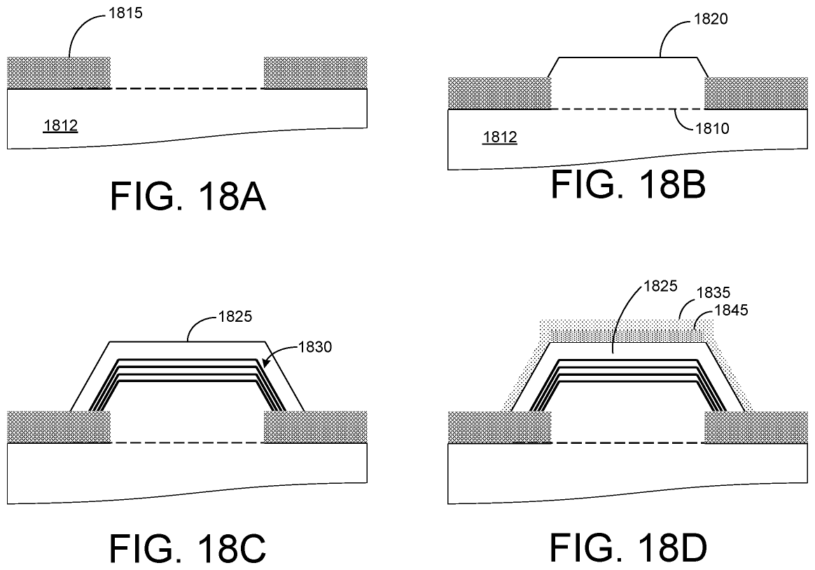

FIGS. 18A to 18D are diagrams illustrating an example process for a producing a μLED and/or μLED mesa, such as, at least, the uLED 200 of FIG. 2 and/or the uLED 300 of FIG. 3, e.g., using epitaxial regrowth processes. As shown, in FIG. 18A, a growth mask 1815 is formed on a substrate 1812. As shown in FIG. 18B, after forming the growth mask 1815, an n-type region 1820 (mesa) with slanted sidewall regions is grown on a growth interface 1810 of the substrate 1812. As shown in FIG. 18C, after growing the n-type region 1820, an MQW region 1830 of the μLED is grown on the n-type region 1820. In some implementations, the MQW region 1830 can include a plurality of QWs. As also shown in FIG. 18C, a p-type region 1825 is also grown (e.g., on the MQW region 1830). In this example, the MQW region 1830 and the p-type region 1825 are conformal with the n-type region 1820, e.g., include slanted portions. As shown in FIG. 18D, after growing the MQW region 1830 and the p-type region 1825, contact layers 1835, and/or dielectric layers 1845 are formed. In some implementations, the contact layers 1835 can also function as mirrors for reflecting light emitted by QWs of the MQW region 1830, e.g., to a light emission surface of the μLED.

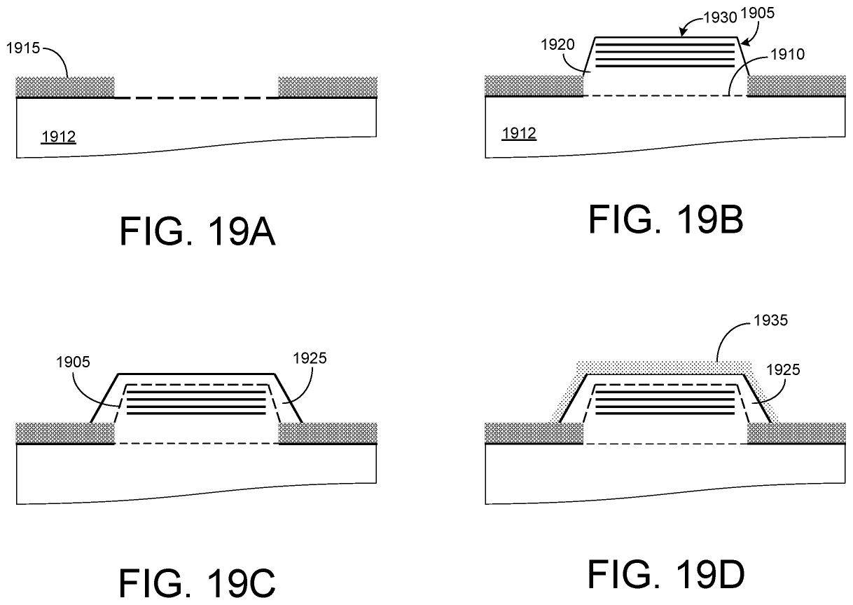

FIGS. 19A to 19D are diagrams illustrating an example process for a producing a μLED and/or μLED mesa, such as, at least, the uLED 600 of FIG. 6, e.g., using epitaxial regrowth processes. As shown, in FIG. 19A, a growth mask 1915 is formed on a substrate 1912. As shown in FIG. 19B, after forming the growth mask 1915, an LED mesa 1905 having slanted sidewall regions is grown on a growth interface 1910 of the substrate 1912. As further shown in FIG. 19B, the LED mesa 1905 includes a n-type region 1920 and a MQW region 1930 (including a plurality of QWs). In this example, the QWs of the MQW region 1930 are planar, e.g., do not include slanted portions. As shown in FIG. 19C, after growing the LED mesa 1905, a p-type region 1925 is grown on the LED mesa 1905, where the p-type region 1925 is conformal with the LED mesa 1905, e.g., includes slanted portions. As shown in FIG. 19D, after growing the p-type region 1925, a contact layer 1935 is formed. In some implementations, the contact layer 1935 can also function as mirrors for reflecting light emitted by the QWs of the MQW region 1930, e.g., to a light emission surface of the μLED. In some implementations, dielectric layers can also be formed, such as in the example μLEDs described herein.

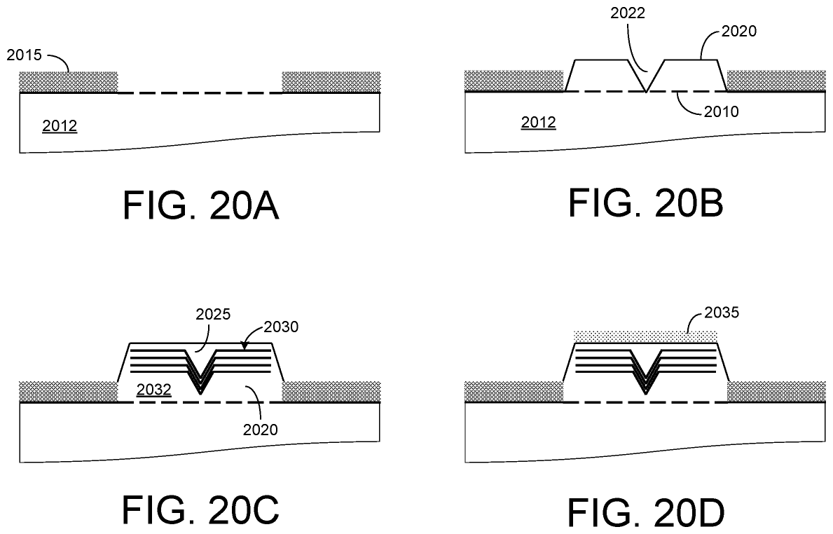

FIGS. 20A to 20D are diagrams illustrating an example process for a producing a μLED and/or μLED mesa, such as, at least, the uLED 700 of FIG. 7, e.g., using epitaxial regrowth processes. As shown, in FIG. 20A, a growth mask 2015 can be formed on a substrate 2012. As shown in FIG. 20B, after forming the growth mask 2015, an n-type region 2020 (mesa) with slanted sidewall regions and a central V-pit region 2022 can be grown on a growth interface 2010 of the substrate 2012. As shown in FIG. 20C, after growing the n-type region 2020, a MQW region 2030, and a p-type region 2025 can be grown on the n-type region 2020, where the MQW region 2030 has a slanted portion 2032 that is conformal with the central V-pit region 2022. The p-type region can fill in the slanted portion 2032 of the MQW region 2030, and be planarized to define an horizontal upper facet of the uLED mesa. As shown in FIG. 20D, after growing and planarizing the p-type region 2025, a contact layer 2035 is formed. In some implementations, the contact layer 2035 can also function as mirrors for reflecting light emitted by QWs of the MQW region 2030, e.g., to a light emission surface of the μLED. In some implementations, dielectric layers can also be formed, such as in the example μLEDs described herein.

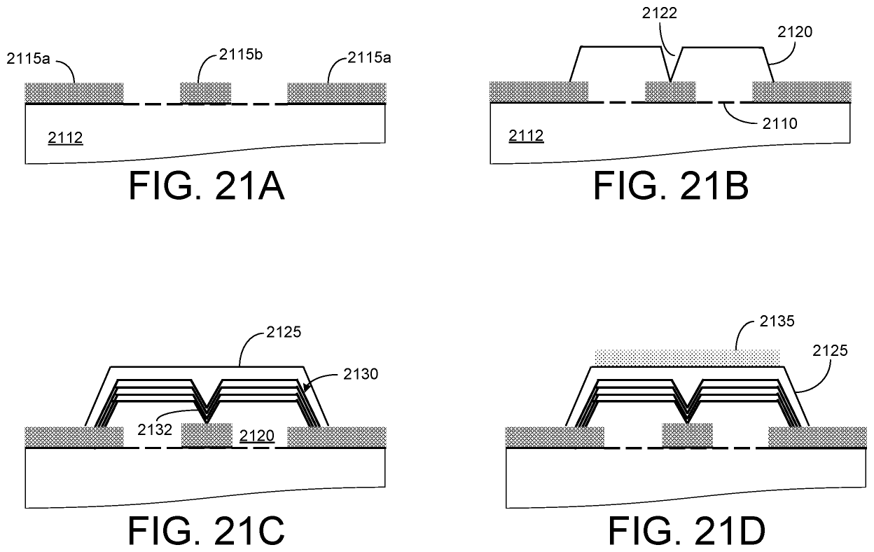

FIGS. 21A to 21D are diagrams illustrating an example process for a producing a μLED and/or μLED mesa, such as, at least, the uLED 800 of FIG. 8, e.g., using epitaxial regrowth processes. As shown, in FIG. 21A, a growth mask 2115a and a growth mask 2115b can be formed on a substrate 2112. As shown in FIG. 21B, after forming the growth mask 2115, an n-type region 2120 (mesa) with slanted sidewall regions and a central V-pit region 2122 can be grown on a growth interface 2110 of the substrate 2112. As shown in FIG. 21C, after growing the n-type region 2120, a MQW region 2130, and a p-type region 2125 can be grown on the n-type region 2120, where the MQW region 2130 has a slanted portion 2132 that is conformal with the central V-pit region 2122, and is also conformal with the slanted sidewalls of the n-type region 2120. The p-type region 2125 can fill in the slanted portion 2132 of the MQW region 2130, and be planarized to define an horizontal upper facet of the uLED mesa. In this example, the p-type region 2125 is also conformal with the slanted sidewalls of the n-type region 2120 and the MQW region 2130. As shown in FIG. 21D, after growing and planarizing the p-type region 2125, a contact layer 2135 is formed on the horizontal upper facet of the μLED defined by the p-type region 2125. In some implementations, the contact layer 2135 can also function as mirrors for reflecting light emitted by QWs of the MQW region 2130, e.g., to a light emission surface of the μLED. In some implementations, dielectric layers can also be formed, such as in the example μLEDs described herein.

In addition to, or in place of the operations of process flows described above, other processing operations can be used. For instance, a μLED mesa may be defined by etching (e.g. dry etch, wet etch), then regrown to form a MQW and/or a slanted region, and regrown (e.g., further regrown) to form a p-doped region. In some implementations, process operations of one method implementation can be performed in another method implementation, e.g. to produces μLEDs with different configurations, such as the example μLEDs described herein.

For instance, in some implementations, a μLED can be produced with QWs that are conformal with a μLED mesa, and have slanted portions present at slanted sidewalls of the μLED mesa. In some implementations, the QWs along the sidewalls can be thinner than QWs along a planar region of the corresponding μLED. In some implementations, the QWs along the sidewalls do not emit a substantial fraction of the light emitted by the μLED, and most (or all) of the light is emitted from the planar portion QWs.

In some implementations, a μLED can have a mesa that includes gallium and nitrogen, e.g. GaN and/or a III-nitride compound. Such compounds may include Ga, In, Al, N and/or other elements. In some implementations, a mesa of a μLED can have a planar top surface corresponding to a c-plane (or a c-plane with a small offcut, e.g., less than 5 degrees) of a crystalline structure of the mesa.

In some implementations, a mesa of a μLED can have slanted sidewalls. The slanted sidewalls can be along a semi-polar direction, corresponding with a respective crystalline structure of the mesa. The mesa can have a hexagonal or circular base shape, such as shown respectively, in FIGS. 28A and 28B. In some implementation, a mesa of a μLED may have six slanted sidewalls along equivalent crystal planes. For instance, the sidewalls can be arranged along semi-polar planes with an m-plane characteristic (e.g., tilted between a m-plane and a c-plane), or along semi-polar plane with an a-plane characteristic (e.g., tilted between an a-plane and a c-plane).

In some implementations, a μLED, or μLED mesa can a lateral dimension L_{D} (e.g., along a horizontal direction, as defined herein) and a diffusion length L across a corresponding QW that is at least L_{D}/5, at least L_{D}/2, or at least L_{D}. In some implementations, this relationship may hold true for the diffusion length for holes, if holes are injected laterally, and it may also hold true for the diffusion lengths of both electrons and holes, if both are injected laterally. In some implementations, having a lateral dimension commensurate with the diffusion length can facilitate substantially uniform lateral carrier injection across a plurality of QWs. In some implementations, a LED (e.g., a μLED μLED mesa) can have a lateral dimension L_{D} that is less than Sum, and the LED can be configured to inject holes into the QWs, where the QWS have a lateral diffusion length L of at least 1 um.

In some implementations, a μLED can include a lateral injection region (e.g., from one or more p-layers into QWs), and the QWs can extend for a distance L_{QW} away from the lateral injection region. In such examples, the epitaxial structure of the μLED can be produced and electrically operated, using the approaches described herein, to achieve a lateral diffusion length L (for electrons and/or holes) that is at least L_{QW}/5, at least L_{QW}/2, at least L_{QW} or at least 2*L_{QW}.

In some implementations, improving performance of a LED (e.g., a uLED), such as the examples described herein can include one or more of the following. A desired target for a performance metric can be selected (e.g. IQE, EQE, WPE, wavelength at an operating current density, etc.), where the selected performance metric is not achieved in an LED where less than 3 quantum wells are substantially injected with carriers. A desired number N of quantum wells for lateral injection can be selected, where N is greater than or equal to 3. A series of LEDs (e.g., different wafers) with at least N quantum wells, and with varying structures (e.g. epitaxial stack, device architecture, contact configuration, and so forth) can be produced, with uniform injection into the N quantum wells increasing over the series. A series of LEDs (e.g., different wafers) with at least N quantum wells, and with varying structures (e.g. epitaxial stack, device architecture, contact configuration) can be produced, with the selected performance metric increasing over the series (e.g. the IQE/EQE/WPE increasing, or the wavelength getting closer to a desired value). As a result of one or more of the foregoing, an LED with substantial lateral injection into the N quantum wells, that achieves the desired performance metric can be obtained.

For instance, in an example implementation, an EQE of at least 10% at a current density of 10 A/cm² can be selected as a desired performance metric. A series of μLED structures with 10 QWs can be grown, where the epitaxial layers are varied across the series (including compositions, thicknesses, and/or doping levels of some epitaxial layers). This can facilitate an increased number of injected quantum wells across the series, and, in turn, lead to obtaining an LED with an increase of EQE to a value above 10%.

In some implementations, a μLED or μLED mesa can have one or more of the following features:

1) A lateral dimension that less than 10 μm, less than 8μm, less than 6 μm, less than 4 μm, less than 3 μm, less than 2 μm, or less than 1.5 μm.
2) A MQW active region, where:

a) QWs of the MQW provide lateral carrier transport.

b) The QWs have a diffusion coefficient of at least 1 cm²/s.

c) The diffusion coefficient is for electrons, for holes, or is an ambipolar diffusion coefficient.

d) The QWs have a diffusion length of at least 0.5 μm, at least 1 μm, at least 2 μm, at least 3 μm, at least 4 μm, at least 6 μm, at least 8 μm, or at least 10 μm for a predetermined operating current (current density).

e) Carrier density in each QW has a lateral uniformity greater than 50%.

f) There are at least 2 QWs, at least 3 QWs, at least 4 QWs, or at least 5 QWs.

3) The LED has an IQE of at least 5%, at least 10%, at least 15%, at least 20%, at least 30%, or at least 50%.

a) The IQE is a peak IQE.

b) The IQE is determined at an operating current density of 10 A/cm².

4) The LED has an EQE of at least 2%, at least 4%, at least 6%, at least 8%, at least 10%, at least 15%, or at least 20%.

a) The EQE is a peak IQE.

b) The EQE is determined at an operating current density of 10 A/cm².

5) The LED has an emission wavelength for emitted light of at least 600 nm, at least 550 nm, at least 520 nm, or at least 430 nm.
6) The current density of operation is in a range 1-100 A/cm², 1-50 A/cm², 1-20 A/cm², 0.1-50 A/cm², 0.1-20 A/cm², or 0.1-10 A/cm².
7) Lateral injection facilitates a reduction in efficiency droop.

a) A relative IQE at an operating current density of 10 A/cm² (relative to a peak IQE) is at least 30%, at least 50%, or at least 70%.

b) The peak IQE is at least 30%, at least 40%, at least 50%, at least 60%, or at least 70%.

8) Lateral injection facilitates injection in multiple QWs, with some QWs on an n-side receiving a substantial hole injection.
9) Less than 50% of injected holes are injected into a top two QWs (e.g., QWs on a p-side).
10) Less than 50% of the light is emitted by a top two QWs.
11) Less than 50% of the holes are confined in the top QW (e.g., a first QW adjacent to the p-side).
12) Less than 50% of emitted light is emitted by the top QW.
13) Diffusion length of holes in the QWs is larger than a lateral dimension of the μLED.
14) Diffusion length of holes in the QWs is larger than a lateral dimension of the LED times a factor of 0.25, times a factor of 0.5, times a factor of 1, times a factor of 2, or times a factor of 5.
15) At least 30%, at least 50%, or at least 70% of holes are injected through interfaces other than horizontal interfaces (e.g., other than an interface arranged along a c-plane).

a) The other interfaces are arranged along semipolar planes.

16) A contact is formed on a non-horizontal surface.

a) The contact is a p-type contact.

b) At least one of the other surfaces is a slanted sidewall.

c) At least one of the other surfaces corresponds to a semipolar pane of a wurtzite crystal structure.

d) The horizontal surface is arranged along (corresponds with) a c-plane of a wurtzite crystal structure.

e) The contact is ohmic.

17) A contact is formed on a horizontal surface.
18) No p-contact is formed on a horizontal surface.
19) The uLED includes a micro-mesa.

a) The micro-mesa has non-vertical sidewalls.

b) The micro-mesa has a c-plane horizontal surface.

c) The micro-mesa has semipolar sidewalls.

20) There is a first p-GaN layer formed on a top (horizontal) surface and a second p-GaN layer formed laterally (e.g. on mesa sidewalls, on non-vertical sidewalls).

a) The first and second p-GaN layers have different doping concentrations.

b) A doping concentration of the first p-GaN layer is less than a doping concentration of the second p-GaN layer.

21) There is a first EBL formed on a top surface and a second EBL formed laterally.

a) The first EBL and the second EBLs have different characteristics (e.g., different compositions, and/or thicknesses).

b) The first EBL and the second EBLs include AlGaN.

22) A first resistance for holes injected from a top surface is different from a second resistance for holes injected laterally.

a) The first resistance is higher than the second resistance.

b) The first and second resistances are contact resistances.

c) The first and second resistances are spreading resistances.

d) The first and second resistances are total resistances.

23) A metallic contact is formed on at least one of a non-vertical sidewalls, or on a horizontal surface.

a) The metallic contact has a reflectivity of at least 80%, at least 90%, or at least 95%.

b) The reflectivity is at normal (orthogonal) incidence, at a peak wavelength of light emission of the μLED.

In some implementations, a μLED can have a geometry as follows:

1) The uLED has a mesa shape, with a horizontal top surface and at least three non-vertical sidewalls.
2) A first portion of the uLED has first epitaxial layers oriented along a horizontal direction, where the first epitaxial layers include a first plurality of quantum wells with a first thickness and a first bandgap.
3) A second portion of the μLED has second epitaxial layers oriented along the non-vertical sidewalls, where the second epitaxial layers include a second plurality of quantum wells with a second thickness and a second bandgap.
4) Contacts are formed on at least one of the horizontal top surface, or on the non-vertical sidewalls.
5) One or more of the following aspects can be present:

a) The first portion of the LED is located near the center of the mesa.

b) The first portion of the LED has a lateral width of at least 500 nm, at least 1 μm, or at least 2 μm.

c) The mesa has a width of less than 20 μm, less than 10 μm, less than 5 μm, or less than 2 μm.

d) The mesa has a height of at least 100 nm, at least 200 nm, at least 500 nm, at least 1 μm, or at least 2 μm.

e) The mesa has a height of less than 10 μm, less than 5 μm, less than 2 μm, or less than 1 μm.

f) The second portion of the μLED is located near the sidewalls of the mesa.

g) The horizontal direction is along a c-plane and the non-vertical sidewalls are along semipolar planes.

h) The non-vertical sidewalls have an angle from the vertical direction that is at least 10 degrees, or at least 20 degrees.

i) The non-vertical sidewalls have an angle from the vertical direction that is less than 80 degrees, or at least 70 degrees.

j) QWs of the first plurality of QWs, and QWs of the second plurality of QWs are respectively connected to each other in a one-to-one relationship.

k) The second bandgap is greater than the first bandgap.

l) The second thickness is less than the first thickness

m) Contacts are formed on the horizontal top surface.

In some implementations, possible electrical contacts include metallic contacts, such as contacts including silver, aluminum, gold, titanium, nickel, platinum, and/or tungsten, as well multi-layer contacts and alloys. In some implementations, transparent metal contacts can be used, such as indium tin oxide, zinc oxide, and/or indium zinc oxide, as well as stacks of transparent metal contact materials.

In some implementations, a μLED can be configured and operated to increase lateral injection as compared to vertical injection. Such approaches may be desirable because vertical injection can lead to carriers spreading to fewer QWs, whereas lateral injection can lead to more QWs being injected for a same total current. Accordingly, in some implementation, a resistance for lateral injection can be lower than a resistance for vertical injection, which can be facilitated by configuration of the respective contact resistances (or even the Schottky barrier heights), by the use of spreading resistances (e.g., achieved through doping and thickness control), and/or by other approaches. In some implementations, an operating current density can be selected (e.g. 10 A/cm2, or at least 10 A/cm2), and a corresponding LED can be configured (produced) to provide current spreading at the selected current density.

In some examples, a plurality of LED mesas can be connected and operated electrically, to provide a light source for a display, and/or to provide a light source for illumination.

In some implementations, producing a μLED can include:

1) Selecting a minimum number of QWs that is higher than one.
2) Selecting an operating current density.
3) Preparing a series of μLEDs with non-vertical sidewalls and corresponding sidewall contacts.
4) Over the series, configuring the epitaxial layers and the sidewall contacts to facilitate lateral injection of carriers and increase IQE at the selected current density.
5) Obtaining a uLED with an IQE may that is at least 10%, at least 20%, at least 30%, at least 40%, or at least 50%.

In some implementations, a method for improving performance of a μLED can include the following:

1) Preparing a series of LEDs having increasing uniformity of carrier injection, where each LED of the series has an IQE, at a predetermined current density, of at least 20%.
2) Determining respective increases in IQEs, at the predetermined current density, between at least two LEDs of the series, where increases in IQE are facilitated by increases in lateral injection.
3) Preparing at least an additional LED of the series by improving lateral injection relative to a previously obtained highest lateral injection.
4) Repeating steps 2 and 3 until an increase in IQE of at least 5% between two LEDs of said series is obtained.
In some implementation of the method, the predetermined current density can be at least 10 A/cm², at least 2 A/cm², at least 5 A/cm², at least 20 A/cm², or at least 50 A/cm².

In some implementations, an active region of a μLED can have QWs separated by barrier layers, and the barrier layers can have a concentration of In (percent composition) of at least 1%, at least 2%, at least 3%, or at least 5%. For instance, the barrier layers can be InGaN layers with an In percent composition of at least 1%, up to 5%. Such approaches can facilitate injection across the barrier layers, and allow for lowering a corresponding μLED's operating voltage. In some implementations, the foregoing example In percent compositions can be for barrier layers in a slanted region of a μLED (e.g., along a semipolar plane), or in a lateral region of a uLED (e.g., a region that is located laterally with respect to a planar region).

In some implementations, uLEDs of different colors (e.g. red, green, and/or blue) can be formed on a same wafer. Combinations of electrical contact schemes can be used. In some implementations, μLEDS of each color can have lateral contacts (and/or lateral carrier injection) and, as a result, can benefit from lateral carrier injection and diffusion. In some implementation, μLEDs of a subset of colors can have lateral contacts (and/or lateral carrier injection). For instance, red LEDs, for which performance may, relative to blue and green LEDs, suffer the most from efficiency droop and/or uneven carrier injection, can achieve more benefit from having lateral contacts and/or lateral carrier injection.

In some implementations, lateral carrier transport in a uLED can occur as a result of following series of events:

1) Holes are injected from a contact layer to a p-material having a slanted orientation, the p-material having a first bandgap and a first thickness.
2) The holes are then injected from the p-material to an intermediate layer having the slanted orientation, a second bandgap, and a second thickness.
3) The holes are injected from the intermediate layer to a plurality of QWs with a planar orientation, a third bandgap and a third thickness.

In some implementation, facilitation of lateral carrier transport in accordance with the foregoing series of event can be achieved where one or more of the following aspects of μLED are present:

1) The uLED has a perimeter that is bound by slanted orientations.
2) The uLED has a perimeter that is bound by p-material.

a) The p-material is located laterally respective to a MQW.

3) The uLED is a mesa with slanted sidewalls along the slanted orientations.
4) The uLED is a mesa with p-material sidewalls.
5) The uLED has one or several inner lateral injection regions, located away from the perimeter, with p-material.

a) The inner lateral regions extend vertically in an MQW region and provide lateral injection in the MQW region.

6) The p-material is p-GaN.
7) The second bandgap is less than the first bandgap, and greater than the third bandgap.
8) The intermediate layer include at least 1% In, at least 2% In, at least 3% In, at least 5% In, or at least 10% In.
9) The QWs include at least 15% In, at least 20% In, at least 30% In, at least 40% In, or at least 50% In.
10) The intermediate layer is a slanted QW.
11) The second thickness is less than the third thickness.
12) The slanted orientation is along a semipolar plane.
13) No more than 30%, no more than 50%, or no more than 70% of the holes are injected into a single QW of the plurality of QWs.
14) The holes diffuse laterally for at least 500 nm, at least 1 um, or at least 2 um in the planar (horizontal) direction in the QWs.
15) The holes are further injected through other layers, such as non-planar EBL layers (e.g. slanted EBL layers, vertical EBL layers), as they are injected from the p-material to the intermediate layer.

While the foregoing discussion is generally directed to uLEDs, in some implementations, the approaches described herein can be used to implement and operate other optoelectronic devices, such as large-scale LEDs (e.g., with lateral dimensions of 100 um or more, 500 um or more, 1 mm or more). In the case of a large LED, a plurality of lateral injection regions may be formed across the LED to promote lateral hole injection. For instance, a plurality of p-doped injection regions, similar to those of FIGS. 7 and 8, can be formed, e.g., by processing operations including etching and regrowth. These injection regions may protrude inside an active region of the LED. Density and spacing of these injection regions may be selected based on the particular implementation. For instance, spacing between injection regions may correspond to a lateral diffusion length associated with QWs of the LED. In some implementations, such injection regions may be formed with a periodic layout (e.g., a square lattice, a triangular lattice, etc.), with a periodicity corresponding to, or commensurate with, an associated diffusion length, such as described herein. In some implementations, a MQW region can have a lateral diffusion length L, a size larger than 5L, and can have lateral injection regions fabricated with a triangular lattice layout, whose period is on the order of L.

In the foregoing discussion regarding vertical carrier transport, and as used herein, slanted refers to an orientation which is neither along a horizontal, nor along a vertical direction (e.g., such as described with respect to the example μLED implantation of FIGS. 1-9). Further, slanted surfaces need not be planar. For instance, slanted surfaces can be curved, and/or can have a varying slope. In the case of a wurtzite III-nitride c-plane LED, the horizontal direction is the c-plane, and the vertical direction can include m-planes and a-planes. Accordingly, slanted orientations are arranged along semipolar planes. Likewise, non-vertical sidewalls, as used herein, refers to sidewalls that are neither horizontal nor vertical. For instance, such non-vertical (slanted) sidewalls can be arranged at an angle of at least 10 degrees, or at least 20 degrees, and at most 80 degrees, or at most 70 degrees with respect to the horizontal direction.

In some example, a LED (e.g., a μLED) can operate with lateral carrier diffusion (lateral carrier transport) occurring in one or more doped semiconductor layers, which may not be active, light-emitting layers. For instance, in some implementations, a μLED can include one or more tunnel junctions (TJs), where a TJ includes an n-doped layer, a p-doped layer, and can include one or more junction layers between the n-doped and the p-doped layer. A TJ can operate such that electrons in an n-doped layer (on a first side of the TJ) tunnel through the TJ and become holes in a p-doped layer (on a second, opposite side of the TJ). In such implementations, a corresponding LED can be configured such that lateral carrier diffusion (e.g., for electrons) occurs in n-doped layers, which can lead to better current spreading than if only p-layers were used for current spreading.

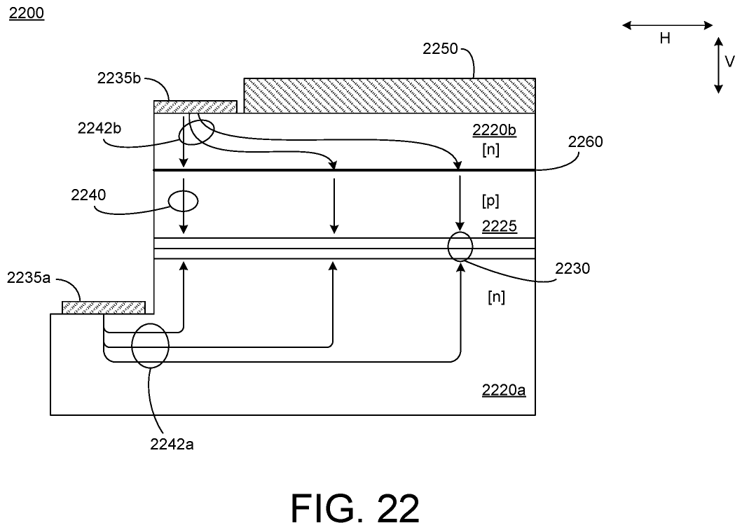

FIG. 22 is a diagram illustrating a LED 2200 including a TJ in which lateral carrier diffusion occurs in doped layers other than QW layers. As shown in FIG. 22, the LED 2200 includes an epitaxial layer stack including an n-doped layer 2220a (which can include an n-type buffer layer, a QW active region 2230, a p-doped layer 2225, a TJ 2260, and a n-doped layer 2220b. A contact 2235a is made to the n-doped layer 2220a (e.g., to a n-type buffer layer). A contact 2235b is made to the n-doped layer 2220b. In this example, electrons diffuse laterally in both the n-doped layer 2220a and the n-doped layer 2220b, as is respectively shown by arrows 2242a and arrows 2242b. In this example, electrons in n-doped layer 2220b tunnel through the TJ 2260 and become holes, which are vertically transported through p-doped layer 2225 to the QW active region 2230, which can include a plurality of QWs. This lateral diffusion of electrons in the n-doped layer 2220b (which are converted to holes by the TJ 2260), and the lateral diffusion of electrons in the n-doped layer 2220 (which are provided to the QW 2230) facilitates uniform lateral carrier distribution in the QW 2230 for both holes and electrons.

In this example, the contact 2235b only contacts (is only disposed on) a portion of n-doped layer 2220b. As shown in FIG. 22, a mirror 2250 is disposed on another portion of an upper surface of the n-doped layer 2220b, which can facilitate reflection of light emitted by the QW active region 2230. In this example, the mirror does not act as an electrical contact. Semiconductor n-type surfaces may be prepared (e.g. by a dry etch, a wet etch, a chemical treatment) before formation of the n-contact; which may reduce the contact resistance.

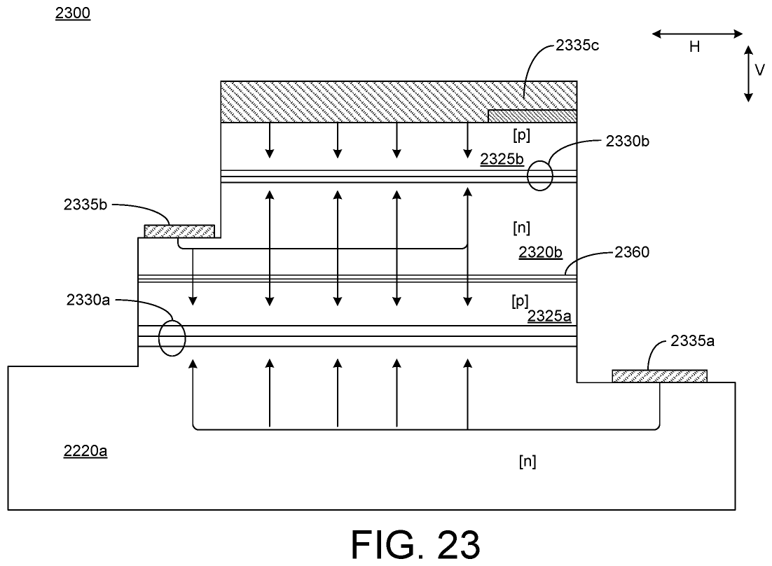

FIG. 23 is a diagram illustrating another LED 2300 including a TJ in which lateral carrier diffusion occurs in doped layers other than QW layers. The LED 2300 includes a number of similar aspects as the LED 2200. For example, the LED 2300 includes an epitaxial layer stack including an n-doped layer 2320a (which can include an n-type buffer layer), a QW active region 2330a, a p-doped layer 2325a, a TJ 2360, and a n-doped layer 2320b. A contact 2335a is made to the n-doped layer 2320a (e.g., to a n-type buffer layer), and a contact 2235b is made to the n-doped layer 2220b. These elements of the LED 2300 correspond with the structure of the LED 2200, and can operate similarly (e.g., emit light from the QW active region 2330a with holes that a converted from electrons by the TJ 2360) when an appropriate voltage is applied between the contact 2335a and the contact 2235b. Accordingly, the details of that operation are not described again here with respect to FIG. 23.

The LED 2300 differs from the LED 2200 in that a QW active region 2330b is disposed on the 2320b, a p-doped layer 2325b is disposed on the QW active region 2330b. A contact 2335c is made to the p-doped layer 2325b, which can uniformly inject holes into the p-doped layer 2325b. By applying an appropriate voltage between the contact 2335c and the 2335b, the QW active region 2330b can be controlled to emit light. For instance, electrons spread laterally in the n-doped layer 2320b, which facilitating uniform electron injection into the QW active region 2330b (or into the TJ 2360 when operating the QW active region 2330a).

In some implementations, a LED can have more than two QW active regions. In such implementation, TJs can be formed between each of the QW active regions (e.g., an LED with three QW active regions can include two TJs). For instance, in some implementations, a diode can have a blue QW active region, a green QW active region, and a red QW active region. By driving appropriate voltages across QW regions, uniform current injection and light emission can be obtained, where the TJs facilitate lateral current spreading and conversion of electrons to holes.

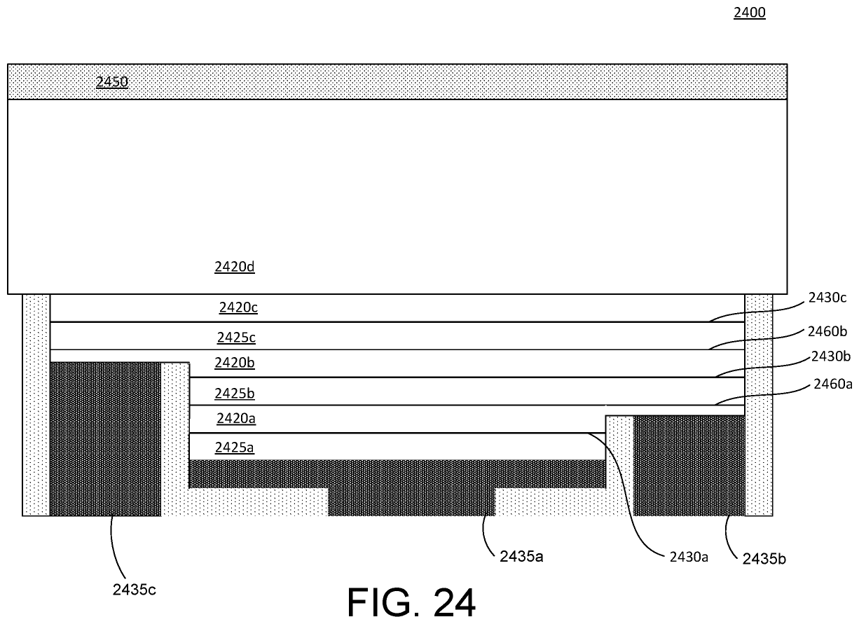

As an example, FIG. 24 illustrates a diode 2400 that includes three QW active regions and two TJs. For instance, the diode 2400, as shown in FIG. 24, includes a red QW active region 2430a, a green QW active region 2430b, and a blue QW active region 2430c. A TJ 2460a is disposed (formed) between the red QW active region 2430a and the green QW active region 2430b. A TJ 2460b is disposed (formed) between the green QW active region 2430b and the blue QW active region 2430c. The diode 2400 also includes n-doped layers 2420a, 2420b and 2420c, an n-type buffer layer 2420d, a substrate 2450, and p-doped layers 2425a, 2425b and 2425c, as indicated in FIG. 24. A further contact (not shown) can be made to the n-type buffer layer 2420d, and/or the n-doped layer 2420c The diode 2400 also includes contacts 2435a, 2435b and 2435c for applying appropriate voltages to operate the QW active regions 2430a-2430c of the diode 2400. In the diode 2400, electrons that are laterally diffused in the n-doped layer 2420a can be converted to holes by the TJ 2460a that that are provided to (injected in) the green QW active region 2430b from the p-doped layer 2425b. Likewise, electrons that are laterally diffused in the n-doped layer 2420b can be converted to holes by the TJ 2460b that are provided to (injected in) the blue QW active region 2430c from the p-doped layer 2425c.

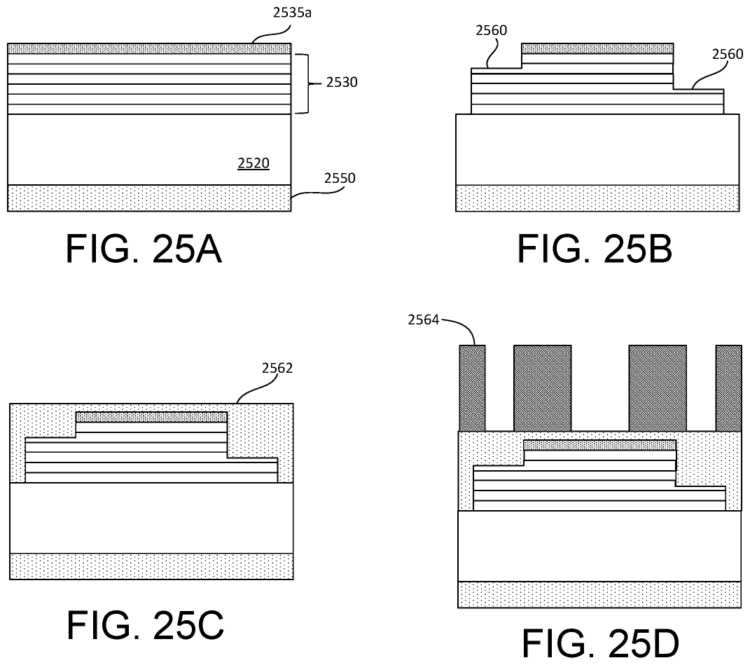

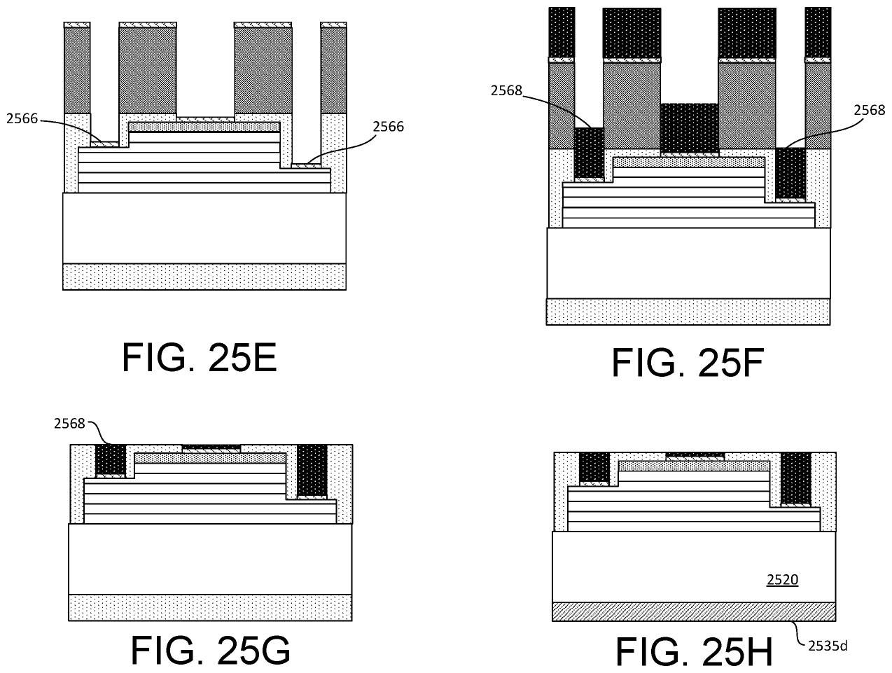

FIGS. 25A to 25H are diagrams illustrating an example process flow for producing an LED with multiple TJs, such as the diode 2400. For purposes of brevity, not all elements of the diode 2400 referenced in FIG. 24 are referenced again in FIGS. 25A-25H, and the processing operations are generally described.

As shown in FIG. 25A, epitaxial layers defining an n-type buffer layer 2520 and an active region 2530, including different color QW region (e.g., red, green and blue QW regions) and multiple TJs, are formed on a growth substrate 2550. As also shown in FIG. 25A, a p-type contact 2535a is formed to the active region 2530 (e.g., to a p-doped layer). As shown in FIG. 25B, etching can be performed to define contact surfaces 2560 for formation of vias to n-doped layers of the active region 2530 (e.g., for lateral diffusion of electrons to respective QWs and TJs of the LED). As shown in FIG. 25 a planarizing dielectric layer 2562 is formed. As illustrated in FIG. 25D, a mask layer 2564 (e.g., a thick photoresist mask) with openings for defining vias and associated contact metal is formed. As shown in FIG. 25D, contact metal 2566 (e.g., n-type contact metal) is formed, such as by using an evaporation process. As shown in FIG. 25F, metal vias 2568 are formed, such as by using an electroplating process. As shown by FIG. 25G, as compared to FIG. 25F, a liftoff process is performed to remove the mask layer 2564 (as well as unneeded contact metal 2566 and/or unneeded via metal 2568). As shown in FIG. 25H, the growth substrate 2550 can then be removed (e.g., using laser lift off and/or a chemical etch), and a backside contact 2435d (e.g., a transparent contact) can be formed to the n-type buffer layer 2520.

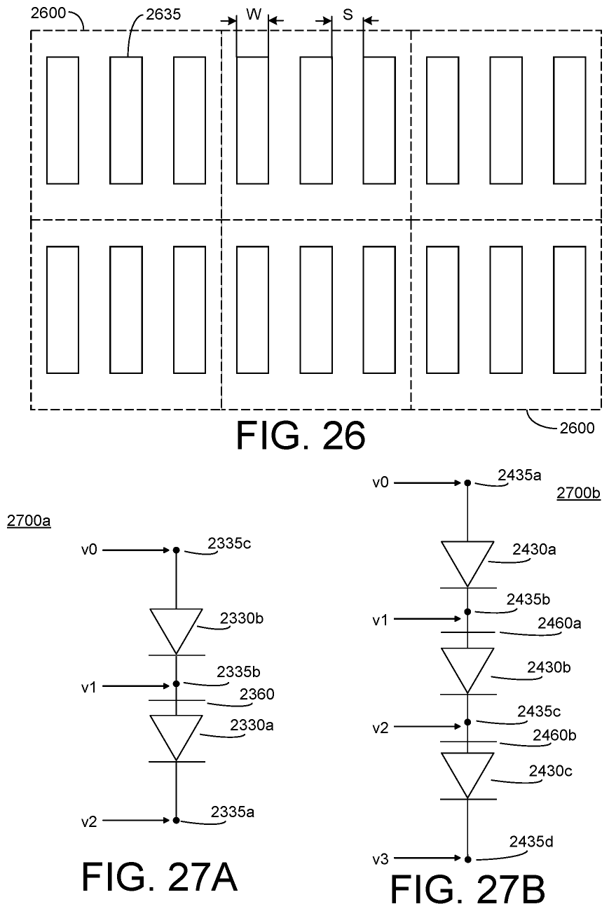

FIG. 26 is a diagram illustrating an example layout for top of the metal vias 2635 of a plurality of diodes, such the example diodes described herein, e.g., the diode 2400. In FIG. 26, a boundary of each pixel 2600 of, e.g., of a corresponding display device, is indicated by a dashed line. As shown in FIG. 26, a spacing S between the vias 2635, and a width W of the vias 2635 are substantially equal. Such an approach can improve alignment tolerance for a bonding process, e.g., when bonding a LED wafer to a backplane, such as a CMOS backplane, presuming that vias on the CMOS backplane side have a similar layout. Accordingly, as long as misalignment is less than S (or W), all vias would be connected.

FIGS. 27A and 27B are circuit schematic diagrams illustrating circuit equivalents of example LEDs, such as the LEDs 2300 and 2400 of FIGS. 23 and 24, respectively, as circuits 2700a and circuit 2700b. For purposes of illustration, the elements in FIGS. 27A and 27B are referenced with reference numbers corresponding to, respectively, FIG. 23 and FIG. 24. Accordingly, FIGS. 27A and 27B are discussed with further reference to corresponding FIGS. 23 and 24.

Referring to FIG. 27A, with further reference to FIG. 23, the contact 2335c is shown as being coupled with an anode of a diode that illustrates (implements) the QW active region 2330b. The contact 2335b is coupled between the diode implementing the QW active region 2330b and a diode implementing the QW active region 2330a. The TJ 2360 is also disposed between the diodes of the circuit 2700a. The contact 2335a is coupled with the cathode of the diode illustrating (implementing) the QW active region 2330a. As shown in FIG. 27, voltages v0, v1 and v2 can be applied to the circuit via the contacts 2335c, 2235b and 2335a, respectively, as appropriate to facilitate operation of the QW active region 2330a and/or the QW active region 2330b.

Referring to FIG. 27B, with further reference to FIG. 24, the contact 2435a is shown as being coupled with an anode of a diode that illustrates (implements) the red QW active region 2430a. The contact 2435b is coupled between the diode implementing the red QW active region 2430a and a diode implementing the green QW active region 2430b. In the circuit 2700b, the TJ 2460a is also disposed between the diodes corresponding with the red QW active region 2430a and the green QW active region 2430b. Also in the circuit 2700b, the contact 2435c is coupled between the diode implementing the green QW active region 2430b and a diode implementing the blue QW active region 2430c. Further in the circuit 2700b, the TJ 2460b is disposed between the diodes corresponding with the green QW active region 2430b and the blue QW active region 2430c. The contact 2335d is coupled with the cathode of the diode implementing the blue QW active region 2430c (which can be a contact to the n-type buffer layer 2420d and/or to the n-doped layer 2420c). As shown in FIG. 27, voltages v0, v1, v2 and v3 can be applied to the circuit 2700b via the contacts 2435a, 2435b, 2435c and 2435c, respectively, as appropriate to facilitate operation of the red QW active region 2430a, the green QW active region 2430b, and/or the blue QW active region 2430c.

FIGS. 28A to 28C are diagrams schematically illustrating example μLED mesa configurations, such as could be used in implementations of the example uLEDs of FIG. 1-9. In the examples of FIGS. 28A to 28C, the vertical direction, as described herein, is into, and out of the page.

FIG. 28A illustrates a mesa 2800a with a hexagonal shape (e.g., a hexagonal base). As shown in FIG. 28A, an upper surface, or a horizontal facet 2805a1 is located in central portion of the mesa 2800a, while slanted sidewalls 2805b1 are located along a perimeter of the mesa 2800a. As shown in FIG. 28A, the horizontal facet 2805a1 can have a lateral dimension of L_{D1}, while the base of the mesa 2800a can have a lateral dimension L_{D2}. The lateral dimensions L_{D1} and L_{D2} can have values such as those described herein. Also, the section line C1-C1 in FIG. 28A can represent a section line corresponding with the views of FIGS. 1-9.

In some implementations, lateral conduction through n-type layers and lateral injection through quantum wells can be combined in an LED. For instance, an LED may have a tunnel junction whose n-layers facilitate lateral spreading of holes outside the QW, and a lateral injection region for injection in the QWs.

FIG. 28B illustrates a mesa 2800b with a circular shape (e.g., a circular base). As shown in FIG. 28B, an upper surface, or a horizontal facet 2805a2 is located in central portion of the mesa 2800b, while slanted sidewalls 2805b2 are located along a perimeter of the mesa 2800b. The mesa 2800b can have lateral dimensions similar to those described with respect to FIG. 28A. Also, the section line C2-C2 in FIG. 28B can represent a section line corresponding with the views of FIGS. 1-9.

FIG. 28C illustrates a mesa 2800c with a square shape (e.g., a square base). As shown in FIG. 28C, an upper surface, or a horizontal facet 2805a3 is located in central portion of the mesa 2800c, while slanted sidewalls 2805b3 are located along a perimeter of the mesa 2800c. The mesa 2800c can also have lateral dimensions similar to those described with respect to FIG. 28A. Also, the section line C3-C3 in FIG. 28C can represent a section line corresponding with the views of FIGS. 1-9.

It will be understood, for purposes of this disclosure, that when an element, such as a layer, a region, or a substrate, is referred to as being on, disposed on, disposed in, connected to, electrically connected to, coupled to, or electrically coupled to another element, it may be directly on, connected or coupled to the other element, or one or more intervening elements may be present. In contrast, when an element is referred to as being directly on, directly disposed on, directly disposed in, directly connected to or directly coupled to another element or layer, there are no intervening elements or layers present. Although the terms directly on, direct in, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to, vertically adjacent to, or horizontally adjacent to.

Some implementations may be implemented using various semiconductor processing and/or packaging techniques. Some implementations may be implemented using various types of semiconductor processing techniques, such as epitaxial growth processes, associated with semiconductor substrates and materials including, but not limited to, for example, silicon (Si), gallium arsenide (GaAs), gallium nitride (GaN), silicon carbide (SiC), and/or so forth.

While certain features of various example implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A method for electrical operation of a micro-LED, the method comprising:
driving the micro-LED with an electrical power via at a p-type contact disposed on at least one of:
a horizontal face of the micro-LED; or
a non-horizontal face of the micro-LED, the p-type contact contacting a p-type layer;
injecting, by driving the micro-LED with the electrical power, holes from the p-type contact into the p-type layer; and
laterally injecting, along the non-horizontal face of the micro-LED, the holes from the p-type layer to a plurality of quantum wells (QWs) having respective horizontal regions arranged along a horizontal direction of the micro-LED, the holes being injected to the plurality of QWs via the p-type semiconductor layer.

2. The method of claim 1, wherein:
the micro-LED has a lateral dimension along the horizontal direction between 0.5 micrometers (μm) and 5 μm; and
the injected holes diffuse laterally in the plurality of QWs over a distance greater than 0.5 μm.

3. The method of claim 1, wherein the non-horizontal face is arranged along a semi-polar plane of the micro-LED.

4. The method of claim 1, wherein at least one QW of the plurality of QWs has a recombination lifetime greater than 5 nanoseconds (ns) corresponding with the driving of the micro-LED with the electrical power.

5. The method of claim 1, wherein driving the micro-LED with the electrical power includes driving the micro-LED with a current density between 1 amp/centimeter-squared (A/cm²) and 100 A/cm².

6. A micro-LED comprising:
a semiconductor mesa having a lateral dimension less than Sum along a horizontal direction of the micro-LED; and
a contact formed on at least one of:
a horizontal face of the semiconductor mesa; or
a non-horizontal face of the semiconductor mesa,
the semiconductor mesa including:
a plurality of quantum wells (QWs); and
a p-type semiconductor layer formed between the contact and the plurality of QWs,
the contact, the p-type semiconductor layer and the plurality of QWs are configured such that:
when the micro-LED is driven at an effective current density less than 50 A/cm², holes are:
injected from the contact to p-type layer; and
laterally injected from the p-type layer to the plurality of QWs, and
the injected holes diffuse laterally in the plurality of QWs over a distance greater than 1 micrometer (μm).

7. The micro-LED of claim 6, wherein the non-horizontal face is a slanted sidewall of the semiconductor mesa, the slanted sidewall being arranged at an angle between 10 degrees and 80 degrees with respect to a line along the horizontal direction.

8. The micro-LED of claim 6, wherein the non-horizontal face is arranged along a semi-polar plane of the semiconductor mesa.

9. The micro-LED of claim 6, wherein:
the plurality of QWs includes at least three QWs; and
respective percentages of the injected holes that are diffused in the at least three QWs are less than 50 percent and greater than 25 percent.

10. A micro-LED mesa comprising:
a semiconductor mesa having a lateral dimension along a horizontal direction of the micro-LED mesa of less than or equal to 5 micrometers (μm);
the semiconductor mesa including:
at least one slanted sidewall;
a planar top surface; and
a multiple quantum well (MQW) portion having a planar region arranged along the planar top surface and a slanted region arranged along the at least one slanted sidewall;
first p-type material disposed on the planar region of the MQW portion;
second p-type material disposed on the slanted region of the MQW portion; and
a p-type contact disposed on the second p-type material.

11. The micro-LED mesa of claim 10, further comprising:
an insulating layer disposed on at least a portion of the first p-type material; and
a reflective layer disposed on the insulating layer.

12. The micro-LED mesa of claim 10, wherein, during electrical operation of the micro-LED mesa:
hole injection occurs at a first carrier density through the first p-type material; and
hole injection occurs at a second carrier density through the second p-type material, the second carrier density being negligible relative to the first carrier density.

13. The micro-LED mesa of claim 10, wherein quantum wells (QWs) of the MQW portion have respective diffusion coefficients of greater than or equal to 1 centimeter-squared per second (cm2/s) at a current density of less than 20 amps per centimeter-squared (A/cm²).

14. The micro-LED mesa of claim 10, wherein, in response to injection of holes from the p-type contact, light is emitted from the MQW portion at a lateral distance along the horizontal direction of greater than or equal to 1 micrometer (μm) from the p-type contact.

15. The micro-LED mesa of claim 10, wherein the micro-LED mesa includes a plurality of GaN-based materials.

16. The micro-LED mesa of claim 15, wherein:
the planar top surface is arranged along a c-plane of at least one of the plurality of GaN based materials; and
the at least one slanted sidewall is arranged along a semi-polar plane of at least one of the plurality of GaN based materials.

17. A micro-LED mesa comprising:
a semiconductor mesa including:
a horizontal top surface arranged along a horizontal direction of the micro-LED mesa;
at least three non-vertical sidewalls;
a plurality of epitaxial layers including:
a first portion arranged along the horizontal direction, the first portion of the plurality of epitaxial layers defining a first plurality of quantum wells (QWs) of a first thickness and a first bandgap; and
a second portion arranged along the at least three non-vertical sidewalls, the second portion of the plurality of epitaxial layers defining a second plurality of QWs of a second thickness and a second bandgap; and
an electrical contact disposed on at least one non-vertical sidewall of the at least three non-vertical sidewalls.

18. The micro-LED mesa of claim 17, wherein the micro-LED mesa is configured such that holes, injected during electrical operation of the micro-LED mesa, travel from the electrical contact to the second plurality of QWs and, then to the first plurality of QWs.

19. The micro-LED mesa of claim 17, wherein the micro-LED mesa is configured such that, during electrical operation of the micro-LED mesa, light is emitted from at least two QWs of the first plurality of QWs.

20. The micro-LED mesa of claim 17, wherein:
the first portion of the plurality of epitaxial layers is included in a central portion of the micro-LED mesa;
the central portion of the micro-LED mesa has a lateral width along the horizontal direction of greater than or equal to 500 nanometers (nm).

21. The micro-LED mesa of claim 17, wherein:
the micro-LED mesa has a width of less than or equal to 20 micrometers (μm);
the micro-LED mesa has a height of greater than or equal to 100 nanometers (nm); and
the height is less than or equal to 10 μm.

22. The micro-LED mesa of claim 17, wherein the second portion of the plurality of epitaxial layers is located in a perimeter portion of the micro-LED mesa.

23. The micro-LED mesa of claim 17, wherein:
the horizontal direction is arranged along a c-plane of a crystalline structure of the micro-LED mesa; and
the at least three non-vertical sidewalls are arranged along respective semipolar planes of the crystalline structure.

24. The micro-LED mesa of claim 17, wherein the at least three non-vertical sidewalls have respective angles from a vertical direction of the micro-LED mesa that are between 10 degrees and 80 degrees.

25. The micro-LED mesa of claim 17, wherein the first plurality of QWs and the second plurality of QWs are connected in a one-to-one relationship.

26. The micro-LED mesa of claim 17, wherein the second bandgap is greater than the first bandgap.

27. The micro-LED mesa of claim 17, wherein the second thickness is less than the first thickness.

28. The micro-LED mesa of claim 17, wherein the electrical contact is a first electrical contact, the micro-LED mesa further comprising:
a second electrical contact disposed on the horizontal top surface.

29. A method for electrical operation of a micro-LED mesa, the micro-LED mesa including:
at least one non-vertical sidewall including:
a p-type material with a first bandgap and a first thickness; and
an epitaxial layer with a second bandgap and a second thickness, the p-type material being disposed on the epitaxial layer;
a plurality of quantum wells (QWs) with a planar orientation along a horizontal direction of the micro-LED mesa, a third bandgap, and a third thickness, the epitaxial layer being disposed between the p-type material and the plurality of QWs; and
an electrical contact disposed on the p-type material,
the first bandgap being greater than the second bandgap, the second bandgap being greater than the third bandgap, and the second thickness being less than the third thickness,
the method comprising:
injecting a plurality of holes from the electrical contact to the p-type material;
injecting the plurality of holes from the p-type material to the epitaxial layer; and
injecting the plurality of holes from the epitaxial layer to at least two QWs of the plurality of QWs.

30. The method of claim 29, wherein the p-type material includes p-type gallium nitride (GaN).

31. The method of claim 29, wherein:
the epitaxial layer is a non-planar and non-vertical QW arranged along a semi-polar plane of the micro-LED mesa, and includes at least 1 percent indium; and
the plurality of QWs with the planar orientation include at least 15 percent indium.

32. The method of claim 29, wherein injecting the plurality of the holes into the plurality of QWs includes injecting no more than 30 percent of the plurality of holes into a single QW of the plurality of QWs.

33. The method of claim 29, wherein the injected plurality of holes diffuse laterally along the horizontal direction in the plurality of QWs for a distance of greater than or equal to 500 nanometers (nm).

34. The method of claim 29, wherein injecting the plurality of holes from the p-type material to the epitaxial layer includes injecting the plurality of holes through an electron blocking layer (EBL).
